(19) United States
(12) Patent Application Publication
(10) Pub. No.: US 2003/0116427 A1
(43) Pub. Date: Jun. 26, 2003

(54) Self-ionized and inductively-coupled plasma for sputtering and resputtering

(75) Inventors: Peijun Ding, San Jose, CA (US); Zheng Xu, Foster City, CA (US); Roderick C. Mosely, Pleasanton, CA (US); Suraj Rengarajan, San Jose, CA (US); Nirmalya Maity, Los Altos, CA (US); Daniel A. Carl, Pleasanton, CA (US); Barry Chin, Saratoga, CA (US); Paul F. Smith, San Jose, CA (US); Darryl Angelo, Sunnyvale, CA (US); Anish Tolia, San Jose, CA (US); Jianming Fu, Palo Alto, CA (US); Fusen Chen, Cupertino, CA (US); Praburam Gopalraja, San Jose, CA (US); Xianmin Tang, San Jose, CA (US); John C. Forster, San Francisco, CA (US)

Correspondence Address: Applied Materials, Inc, Patent Counsel, P.O. Box 450A, Santa Clara, CA, 95052, US

(73) Assignee: Applied Materials, Inc.

(21) Appl. No.: 10/202,778

(22) Filed: Jul. 25, 2002

Related U.S. Application Data
(60) Provisional application No. 60/316,137, filed on Aug. 30, 2001.
(60) Provisional application No. 60/342,608, filed on Dec. 21, 2001.

(51) Int. Cl. C23C 14/32; C23C 14/34

(52) U.S. Cl. 204/192.17; 204/192.12; 204/192.15; 204/298.06; 204/298.08; 204/298.19; 204/298.2; 204/192.11; 204/298.25

(57) ABSTRACT

A magnetron sputter reactor for sputtering deposition materials such as tantalum, tantalum nitride and copper, for example, and its method of use, in which self-ionized plasma (SIP) sputtering and inductively coupled plasma (ICP) sputtering are promoted, either together or alternately, in the same chamber. Also, bottom coverage may be thinned or eliminated by ICP resputtering. SIP is promoted by a small magnetron having poles of unequal magnetic strength and a high power applied to the target during sputtering. ICP is provided by one or more RF coils which inductively couple RF energy into a plasma. The combined SIP-ICP layers can act as a liner or barrier or seed or nucleation layer for hole. In addition, an RF coil may be sputtered to provide protective material during ICP resputtering.

### RELATED APPLICATIONS

This application claims priority of provisional application Serial No. 60/342,608 filed Dec. 21, 2001 and provisional application Serial No. 60/316,137 filed Aug. 30, 2001, which are incorporated by reference in their entireties.

### FIELD OF THE INVENTION

The inventions relate generally to sputtering and resputtering. In particular, the invention relates to the sputter deposition of material and resputtering of deposited material in the formation of semiconductor integrated circuits.

### BACKGROUND ART

Semiconductor integrated circuits typically include multiple levels of metallization to provide electrical connections between large numbers of active semiconductor devices. Advanced integrated circuits, particularly those for microprocessors, may include five or more metallization levels. In the past, aluminum has been the favored metallization, but copper has been developed as a metallization for advanced integrated circuits.

A typical metallization level is illustrated in the cross-sectional view of FIG. 1. A lower-level layer 110 includes a conductive feature 112. If the lower-level layer 110 is a lower-level dielectric layer, such as silica or other insulating material, the conductive feature 112 may be a lower-level copper metallization, and the vertical portion of the upper-level metallization is referred to as a via since it interconnects two levels of metallization. If the lower-level layer 110 is a silicon layer, the conductive feature 112 may a doped silicon region, and the vertical portion of the upper-level metallization formed in a hole is referred to as a contact because it electrically contacts silicon. An upper-level dielectric layer 114 is deposited over the lower-level dielectric layer 110 and the lower-level metallization 112. There are yet other shapes for the holes including lines and trenches. Also, in dual damascene and similar interconnect structures, as described below, the holes have a complex shape. In some applications, the hole may not extend through the dielectric layer. The following discussion will refer to only via holes, but in most circumstances the discussion applies equally well to other types of holes with only a few modifications well known in the art.

Conventionally, the dielectric is silicon oxide formed by plasma-enhanced chemical vapor deposition (PECVD) using tetraethylorthosilicate (TEOS) as the precursor. However, low-k materials of other compositions and deposition techniques are being considered. Some of the low-k dielectrics being developed can be characterized as silicates, such as fluorinated silicate glasses. Hereafter, only silicate (oxide) dielectrics will be directly described, but it is contemplated that other dielectric compositions may be used.

A via hole is etched into the upper-level dielectric layer 114 typically using, in the case of silicate dielectrics, a fluorine-based plasma etching process. In advanced integrated circuits, the via holes may have widths as low as 0.18 μm or even less. The thickness of the dielectric layer 114 is usually at least 0.7 μm, and sometimes twice this, so that the aspect ratio of the hole may be 4:1 or greater. Aspect ratios of 6:1 and greater are being proposed. Furthermore, in most circumstances, the via hole should have a vertical profile.

A liner layer 116 may be deposited onto the bottom and sides of the hole and above the dielectric layer 114. The liner 116 can perform several functions. It can act as an adhesion layer between the dielectric and the metal since metal films tend to peel from oxides. It can also act as a barrier against inter-diffusion between the oxide-based dielectric and the metal. It may also act as a seed and nucleation layer to promote the uniform adhesion and growth and possibly low-temperature reflow for the deposition of metal filling the hole and to nucleated the even growth of a separate seed layer. One or more liner layers may be deposited, in which one layer may function primarily as a barrier layer and others may function primarily as adhesion, seed or nucleation layers.

An interconnect layer 118 of a conductive metal such as copper, for example, is then deposited over the liner layer 116 to fill the hole and to cover the top of the dielectric layer 114. Conventional aluminum metallizations are patterned into horizontal interconnects by selective etching of the planar portion of the metal layer 118. However, a preferred technique for copper metallization, called dual damascene, forms the hole in the dielectric layer 114 into two connected portions, the first being narrow vias through the bottom portion of the dielectric and the second being wider trenches in the surface portion which interconnect the vias. After the metal deposition, chemical mechanical polishing (CMP) is performed which removes the relatively soft copper exposed above the dielectric oxide but which stops on the harder oxide. As a result, multiple copper-filled trenches of the upper level, similar to the conductive feature 112 of the next lower level, are isolated from each other. The copper filled trenches act as horizontal interconnects between the copper-filled vias. The combination of dual damascene and CMP eliminates the need to etch copper. Several layer structures and etching sequences have been developed for dual damascene, and other metallization structures have similar fabrication requirements.

Lining and filling via holes and similar high aspect-ratio structures, such as occur in dual damascene, have presented a continuing challenge as their aspect ratios continue to increase. Aspect ratios of 4.1 are common and the value will further increase. An aspect ratio as used herein is defined as the ratio of the depth of the hole to narrowest width of the hole, usually near its top surface. Via widths of 0.18 μm are also common and the value will further decrease. For advanced copper interconnects formed in oxide dielectrics, the formation of the barrier layer tends to be distinctly separate from the nucleation and seed layer. The diffusion barrier may be formed from a bilayer of Ta/TaN, W/WN, or Ti/TiN, or of other structures. Barrier thicknesses of 10 to 50 nm are typical. For copper interconnects, it has been found useful to deposit one or more copper layers to fulfill the nucleation and seed functions.

The deposition of the liner layer or the metallization by conventional physical vapor deposition (PVD), also called sputtering, is relatively fast. A DC magnetron sputtering reactor has a target which is composed of the metal to be sputter deposited and which is powered by a DC electrical source. The magnetron is scanned about the back of the target and projects its magnetic field into the portion of the reactor adjacent the target to increase the plasma density there to thereby increase the sputtering rate. However, conventional DC sputtering (which will be referred to as PVD in contrast to other types of sputtering to be introduced) predominantly sputters neutral atoms. The typical ion densities in PVD are often less than 10⁹ cm⁻³. PVD also tends to sputter atoms into a wide angular distribution, typically having a cosine dependence about the target normal. Such a wide distribution can be disadvantageous for filling a deep and narrow via hole 122 such as that illustrated in FIG. 2, in which a barrier layer 124 has already been deposited. The large number of off-angle sputter particles can cause a layer 126 to preferentially deposit around the upper corners of the hole 122 and form overhangs 128. Large overhangs can further restrict entry into the hole 122 and cause inadequate coverage of the sidewalls 130 and bottom 132 of the hole 122. Also, the overhangs 128 can bridge the hole 122 before it is filled and create a void 134 in the metallization within the hole 122. Once a void 134 has formed, it is often difficult to reflow it out by heating the metallization to near its melting point. Even a small void can introduce reliability problems. If a second metallization deposition step is planned, such as by electroplating, the bridged overhang make subsequent deposition more difficult.

One approach to ameliorate the overhang problem is long-throw sputtering in which the sputtering target is spaced relatively far from the wafer or other substrate being sputter coated. For example, the target-to-wafer spacing can be at least 50% of wafer diameter, preferably more than 90%, and more preferably more than 140%. As a result, the off-angle portion of the sputtering distribution is preferentially directed to the chamber walls, but the central angle portion remains directed substantially to the wafer. The truncated angular distribution can cause a higher fraction of the sputter particles to be directed deeply into the hole 122 and reduce the extent of the overhangs 128. A similar effect can be accomplished by positioning a collimator between the target and wafer. Because the collimator has a large number of holes of high aspect ratio, the off-angle sputter particles tend to strike the sidewalls of the collimator, and the central-angle particles tend to pass through. Both long-throw targets and collimators typically reduce the flux of sputter particles reaching the wafer and thus tend to reduce the sputter deposition rate. The reduction can become more pronounced as throws are lengthened or as collimation is tightened to accommodate via holes of increasing aspect ratios.

Also, the length that long throw sputtering may be increased may be limited. At the few milliTorr of argon pressure often used in PVD sputtering, there is a greater possibility of the argon scattering the sputtered particles as the target to wafer spacing increases. Hence, the geometric selection of the forward particles may be decreased. A yet further problem with both long throw and collimation is that the reduced metal flux can result in a longer deposition period which can not only reduce throughput, but also tends to increase the maximum temperature the wafer experiences during sputtering. Still further, long throw sputtering can reduce over hangs and provide good coverage in the middle and upper portions of the sidewalls, but the lower sidewall and bottom coverage can be less than satisfactory.

Another technique for deep hole lining and filling is sputtering using a high-density plasma (HDP) in a sputtering process called ionized metal plating (IMP). A typical high-density plasma is one having an average plasma density across the plasma, exclusive of the plasma sheaths, of at least 10¹¹ cm⁻³, and preferably at least 10¹² cm⁻³. In IMP deposition, a separate plasma source region is formed in a region away from the wafer, for example, by inductively coupling RF power into a plasma from an electrical coil wrapped around a plasma source region between the target and the wafer. The plasma generated in this fashion is referred to as an inductively coupled plasma (ICP). An HDP chamber having this configuration is commercially available from Applied Materials of Santa Clara, Calif. as the HDP PVD Reactor. Other HDP sputter reactors are available. The higher power ionizes not only the argon working gas, but also significantly increases the ionization fraction of the sputtered atoms, that is, produces metal ions. The wafer either self-charges to a negative potential or is RF biased to control its DC potential. The metal ions are accelerated across the plasma sheath as they approach the negatively biased wafer. As a result, their angular distribution becomes strongly peaked in the forward direction so that they are drawn deeply into the via hole. Overhangs become much less of a problem in IMP sputtering. and bottom coverage and bottom sidewall coverage are relatively high.

IMP sputtering using a remote plasma source is usually performed at a higher pressure such as 30 milliTorr or higher. The higher pressures and a high-density plasma can produce a very large number of argon ions, which are also accelerated across the plasma sheath to the surface being sputter deposited. The argon ion energy is often dissipated as heat directly into the film being formed. Copper can dewet from tantalum nitride and other barrier materials at elevated temperatures experienced in IMP, even at temperatures as low at 50 to 75 C. Further, the argon tends to become embedded in the developing film. IMP can deposit a copper film as illustrated at 136 in the cross-sectional view of FIG. 3, having a surface morphology that is rough or discontinuous. If so, such a film may not promote hole filling, particularly when the liner is being used as the electrode for electroplating.

Another technique for depositing metals is sustained self-sputtering (SSS), as is described by Fu et al. in U.S. patent application Ser. No. 08/854,008, filed May 8, 1997 and by Fu in U.S. Pat. No. 6,183,614 B1, Ser. No. 09/373,097, filed Aug. 12, 1999. For example, at a sufficiently high plasma density adjacent a copper target, a sufficiently high density of copper ions develops that the copper ions will resputter the copper target with yield over unity. The supply of argon working gas can then be eliminated or at least reduced to a very low pressure while the copper plasma persists. Aluminum is believed to be not readily susceptible to SSS. Some other materials, such as Pd, Pt, Ag, and Au can also undergo SSS.

Depositing copper or other metals by sustained self-sputtering of copper has a number of advantages. The sputtering rate in SSS tends to be high. There is a high fraction of copper ions which can be accelerated across the plasma sheath and toward a biased wafer, thus increasing the directionality of the sputter flux. Chamber pressures may be made very low, often limited by leakage of backside cooling gas, thereby reducing wafer heating from the argon ions and decreasing scattering of the metal particles by the argon.

Techniques and reactor structures have been developed to promote sustained self-sputtering. It has been observed that some sputter materials not subject to SSS because of sub-unity resputter yields nonetheless benefit from these same techniques and structures, presumably because of partial self-sputtering, which results in a partial self-ionized plasma (SIP). Furthermore, it is often advantageous to sputter copper with a low but finite argon pressure even though SSS without any argon working gas is achievable. Hence, SIP sputtering is the preferred terminology for the more generic sputtering process involving a reduced or zero pressure of working gas so that SSS is a type of SIP.

Metal may also be deposited by chemical vapor deposition (CVD) using metallo-organic precursors, such as Cu-HFAC-VTMS, commercially available from Schumacher in a proprietary blend with additional additives under the trade name CupraSelect. A thermal CVD process may be used with this precursor, as is very well known in the art, but plasma enhanced CVD (PECVD) is also possible. The CVD process is capable of depositing a nearly conformal film even in the high aspect-ratio holes. For example, a film may be deposited by CVD as a thin seed layer, and then PVD or other techniques may be used for final hole filling. However, CVD copper seed layers have often been observed to be rough. The roughness can detract from its use as a seed layer and more particularly as a reflow layer promoting the low temperature reflow of after deposited copper deep into hole. Also, the roughness indicates that a relatively thick CVD copper layer of the order of 50 nm may be needed to reliably coat a continuous seed layer. For the narrower via holes now being considered, a CVD copper seed layer of a certain thickness may nearly fill the hole. However, complete fills performed by CVD can suffer from center seams, which may impact device reliability.

Another, combination technique uses IMP sputtering to deposit a thin copper nucleation layer, sometimes referred to as a flash deposition, and a thicker CVD copper seed layer is deposited on the IMP layer. However, as was illustrated in FIG. 3, the IMP layer 136 can be rough, and the CVD layer tends to conformally follow the roughened substrate. Hence, the CVD layer over an IMP layer will also tend to be rough.

Electrochemical plating (ECP) is yet another copper deposition technique that is being developed. In this method, the wafer is immersed in a copper electrolytic bath. The wafer is electrically biased with respect to the bath, and copper electrochemically deposits on the wafer in a generally conformal process. Electroless plating techniques are also available. Electroplating and its related processes are advantageous because they can be performed with simple equipment at atmospheric pressure, the deposition rates are high, and the liquid processing is consistent with the subsequent chemical mechanical polishing.

Electroplating, however, imposes its own requirements. A seed and adhesion layer is usually provided on top of the barrier layer, such as of Ta/TaN, to nucleate the electroplated copper and adhere it to the barrier material. Furthermore, the generally insulating structure surrounding the via hole 122 requires that an electroplating electrode be formed between the dielectric layer 114 and the via hole 122. Tantalum and other barrier materials are typically relatively poor electrical conductors, and the usual nitride sublayer of the barrier layer 124 which faces the via hole 122 (containing the copper electrolyte) is even less conductive for the long transverse current paths needed in electroplating. Hence, a good conductive seed and adhesion layer are often deposited to facilitate the electroplating effectively filling the bottom of the via hole.

A copper seed layer deposited over the barrier layer 124 is typically used as the electroplating electrode. However, a continuous, smooth, and uniform film is preferred. Otherwise, the electroplating current will be directed only to the areas covered with copper or be preferentially directed to areas covered with thicker copper. Depositing the copper seed layer presents its own difficulties. An IMP deposited seed layer provides good bottom coverage in high aspect-ratio holes, but its sidewall coverage can be small such that that the resulting thin films can be rough or discontinuous. A thin CVD deposited seed can also be too rough. A thicker CVD seed layer or CVD copper over IMP copper, may require an excessively thick seed layer to achieve the required continuity. Also, the electroplating electrode primarily operates on the entire hole sidewalls so that high sidewall coverage is desired. Long throw provides adequate sidewall coverage, but the bottom coverage may not be sufficient.

### SUMMARIES OF ILLUSTRATIVE EMBODIMENTS

One embodiment of the present inventions is directed to sputter depositing a liner material such as tantalum or tantalum nitride, by combining long-throw sputtering, self-ionized plasma (SIP) sputtering, inductively-coupled plasma (ICP) resputtering, and coil sputtering in one chamber. Long-throw sputtering is characterized by a relatively high ratio of the target-to-substrate distance and the substrate diameter. Long-throw SIP sputtering promotes deep hole coating of both the ionized and neutral deposition material components. ICP resputtering can reduce the thickness of layer bottom coverage of deep holes to reduce contact resistance. During ICP resputtering, ICP coil sputtering can deposit a protective layer, particularly on areas such as adjacent the hole openings where thinning by resputtering may not be desired.

Another embodiment of the present inventions is directed to sputter depositing an interconnect material such as copper, by combining long-throw sputtering, self-ionized plasma (SIP) sputtering and inductively-coupled plasma (ICP) sputtering in one chamber. Again, long-throw SIP sputtering promotes deep hole coating of both the ionized and neutral copper components. ICP sputtering promotes increased metal ionization for good bottom coverage of deep holes.

SIP tends to be promoted by low pressures of less than 5 milliTorr, preferably less than 2 milliTorr, and more preferably less than 1 milliTorr. SIP, particularly at these low pressures, tends to be promoted by magnetrons having relatively small areas to thereby increase the target power density, and by magnetrons having asymmetric magnets causing the magnetic field to penetrate farther toward the substrate. In one embodiment, SIP may also be also promoted by an electrically floating sputtering shield extending relatively far away from the target, preferably in the range of 6 to 10 cm. ICP sputtering may be promoted by providing one or more RF coils disposed around a plasma generation area. RF energy is inductively coupled into the area to generate and maintain a plasma. Accordingly to one aspect of the invention, the sputtering conditions are controlled to alternate between SIP and ICP sputtering or to otherwise provide a balance between SIP and ICP sputtering to thereby control the ratio of metal ions and neutral metal atoms in the sputter flux.

The inventions may he used to deposit a seed layer, promoting the nucleation or seeding of an after deposited layer, particularly useful for forming narrow and deep vias or contacts through a dielectric layer. A further layer may be deposited by electrochemical plating (ECP). In another embodiment, a further layer is be deposited by chemical vapor deposition (CVD). The CVD layer may itself be used as a seed layer for subsequent ECP, or the CVD layer may completely fill the hole, especially for very high aspect-ratio holes.

There are additional aspects to the present inventions as discussed below. It should therefore be understood that the preceding is merely a brief summary of some embodiments and aspects of the present inventions. Additional embodiments and aspects of the present inventions are referenced below. It should further be understood that numerous changes to the disclosed embodiments can be made without departing from the spirit or scope of the inventions. The preceding summary therefore is not meant to limit the scope of the inventions. Rather, the scope of the inventions is to be determined only by the appended claims and their equivalents.

### BRIEF DESCRIPTION OF THE DRAWINGS

FIG. 1 is a cross-sectional view of a via filled with a metallization, which also covers the top of the dielectric, as practiced in the prior art.

FIG. 2 is a cross-sectional view of a via during its filling with metallization, which overhangs and closes off the via hole.

FIG. 3 is a cross-sectional view of a via having a rough seed layer deposited by ionized metal plating.

FIG. 4 is a schematic representation of a sputtering chamber usable with an embodiment of the invention.

FIG. 5 is a schematic representation of electrical interconnections of various components of the sputtering chamber of FIG. 4.

FIG. 6 is an enlarged view of a portion of FIG. 4 detailing the target, shields, coil, standoffs, isolators and target O-ring.

FIG. 7 is a graph illustrating the relationship between the length of a floating shield and the minimum pressure for supporting a plasma.

FIGS. 8A-8E are cross-sectional views of a via liner and via liner formation process according to one embodiment of the invention.

FIG. 9 is a cross-sectional view of via metallization formed in accordance with a process according to one embodiment of the invention.

FIG. 10 is a schematic representation of a sputtering chamber in accordance with an alternative embodiment of the inventions.

FIG. 11 is a schematic representation of electrical interconnections of various components of the sputtering chamber of FIG. 10.

FIGS. 12A and 12B are graphs plotting ion current flux across the wafer for two different magnetrons and different operating conditions.

FIG. 13A is a cross-sectional view of a via metallization according to an SIP process.

FIG. 13B is a cross-sectional view of a via metallization according to an alternative SIP process.

FIG. 14 is a flow diagram of a plasma ignition sequence which reduces heating of the wafer.

FIG. 15 is a schematic view of a integrated processing tool on which an embodiment of the invention may be practiced.

### DESCRIPTIONS OF ILLUSTRATIVE EMBODIMENTS

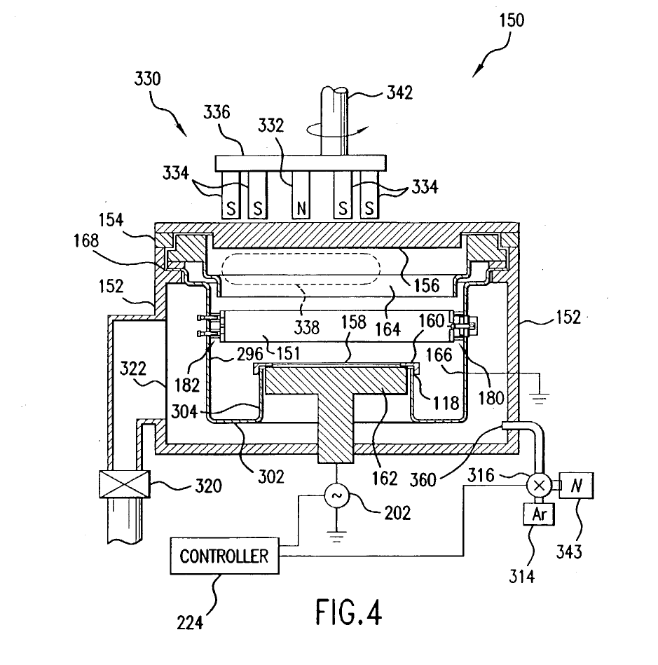

The distribution between sidewall and bottom coverage in a DC magnetron sputtering reactor can be tailored to produce a metal layer such as a liner layer having a desired profile in a hole or via in a dielectric layer. A SIP film sputter deposited into a high-aspect ratio via can have favorable upper sidewall coverage and tends not to develop overhangs. Where desired, bottom coverage may be thinned or eliminated by ICP resputtering of the bottom of the via. In accordance with one aspect of the present inventions, the advantages of both types of sputtering can be obtained in a reactor which combines selected aspects of both SIP and ICP plasma generation techniques, preferably in separate steps. An example of such a reactor is illustrated generally at 150 in FIG. 4. In addition, upper portions of a liner layer sidewall may be protected from resputtering by sputtering an ICP coil 151 located within the chamber to deposit coil material onto the substrate.

The reactor 150 may also be used to sputter deposit a metal layer such as an interconnect layer using both SIP and ICP generated plasmas, preferably in combination, but alternatively, alternately. The distribution between ionized and neutral atomic flux in a DC magnetron sputtering reactor can be tailored to produce a conformal coating in a hole or via in a dielectric layer. As previously mentioned, a SIP film sputter deposited into a high-aspect ratio hole can have favorable upper sidewall coverage and tends not to develop overhangs. On the other hand, an ICP generated plasma can increase metal ionization such that a film sputter deposited into such a hole may have good bottom and bottom corner coverage. In accordance with yet another aspect of the present inventions, the advantages of both types of sputtering can be obtained in a reactor, such as the reactor 150, which combines selected aspects of both deposition techniques. In addition, coil material may be sputtered to contribute to the deposition layer as well, if desired.

The reactor 150 of the illustrated embodiment is a DC magnetron type reactor based on a modification of the Endura PVD Reactor available from Applied Materials, Inc. of Santa Clara, Calif. The reactor 150 includes a vacuum chamber 152, usually of metal and electrically grounded, sealed through a target isolator 154 to a PVD target 156 having at least a surface portion composed of the material to be sputter deposited on a wafer 158. Although the target sputtering surface is depicted as being planar in the drawings, it is appreciated that the target sputtering surface or surfaces may have a variety of shapes including vaulted and cylindrical. The wafer may be different sizes including 150, 200, 300 and 450 mm. The illustrated reactor 150 is capable of self-ionized sputtering (SIP) in a long-throw mode. This SIP mode may be used in one embodiment in which nonconformal coverage is desired such as coverage primarily directed to the sidewalls of the hole. The SIP mode may be used to achieve conformal coverage also.

The reactor 150 also has an RF coil 151 which inductively couples RF energy into the interior of the reactor. The RF energy provided by the coil 151 ionizes a precursor gas such as argon to maintain a plasma to resputter a deposition layer using ionized argon to thin bottom coverage, or to ionize sputtered deposition material to improve bottom coverage. In one embodiment, rather than maintain the plasma at a relatively high pressure, such as 20-60 mTorr typical for high density IMP processes, the pressure is preferably maintained at a substantially lower pressure, such as 1 mTorr for deposition of tantalum nitride or 2.5 mTorr for deposition of tantalum, for example. However, a pressure in the range of 0.1 to 40 mTorr may be appropriate, depending upon the application. As a consequence, it is believed that the ionization rate within the reactor 150 will be substantially lower than that of the typical high density IMP process. This plasma may be used to resputter a deposited layer or to ionize sputtered deposition material or, or both. Still further, the coil 151 itself may be sputtered to provide a protective coating on the wafer during resputtering of the material deposited onto the wafer for those areas in which thinning of the deposited material is not desired, or to otherwise provide additional deposition material.

In one embodiment, it is believed that good upper sidewall coverage and bottom corner coverage can be achieved in a multi-step process in which in one step, little or no RF power is applied to the coils. Thus, in one step, ionization of the sputtered target deposition material would occur primarily as a result of the self-ionization. Consequently, it is believed that good upper sidewall coverage may be achieved. In a second step and preferably in the same chamber, RF power may be applied to the coil 151 while low or no power is applied to the target. In this embodiment, little or no material would be sputtered from the target 156 while ionization of a precursor gas would occur primarily as a result of the RF energy inductively coupled by the coil 151. The ICP plasma may be directed to thin or eliminate bottom coverage by etching or resputtering to reduce barrier layer resistance at the bottom of the hole. In addition, the coil 151 may be sputtered to deposit protective material where thinning is not desired. In one embodiment, the pressure may be kept relatively low such that the plasma density is relatively low to reduce ionization of the sputtered deposition material from the coil. As a result, sputtered coil material can remain largely neutral so as to deposit primarily onto upper sidewalls to protect those portions from thinning.

Since the illustrated reactor 150 is capable of self-ionized sputtering, deposition material may be ionized not only as a result of the plasma maintained by the RF coil 151, but also by the sputtering of the target 156 itself. When it is desired to deposit a conformal layer, it is believed that the combined SIP and ICP ionization processes provide sufficient ionized material for good bottom and bottom corner coverage. However, it is also believed that the lower ionization rate of the low pressure plasma provided by the RF coil 151allows sufficient neutral sputtered material to remain un-ionized so as to be deposited on the upper sidewalls. Thus, it is believed that the combined sources of ionized deposition material can provide both good upper sidewall coverage as well as good bottom and bottom corner coverage as explained in greater detail below.

In an alternative embodiment, it is believed that good upper sidewall coverage, bottom coverage and bottom corner coverage can be achieved in a multi-step process in which in one step, little or no RF power is applied to the coils. Thus, in one step, ionization of the deposition material would occur primarily as a result of the self-ionization. Consequently, it is believed that good upper sidewall coverage may be achieved. In a second step and preferably in the same chamber, RF power may be applied to the coil 151. In addition, in one embodiment, the pressure may be raised substantially such that a high density plasma may be maintained. As a result, it is believed that good bottom and bottom corner coverage may be achieved in the second step.

A wafer clamp 160 holds the wafer 158 on a pedestal electrode 162. Resistive heaters, refrigerant channels, and thermal transfer gas cavity in the pedestal 162 can be provided to allow the temperature of the pedestal to be controlled to temperatures of less than −40° C. to thereby allow the wafer temperature to be similarly controlled.

A darkspace shield 164 and a chamber shield 166 separated by a second dielectric shield isolator 168 are held within the chamber 152 to protect the chamber wall 152 from the sputtered material. In the illustrated embodiment, both the darkspace shield 164 and the chamber shield 166 are grounded. However, in some embodiments, shields may be floating or biased to a nonground level. The chamber shield 166 also acts as the anode grounding plane in opposition to the cathode target 156, thereby capacitively supporting a plasma. If the darkspace shield is permitted to float electrically, some electrons can deposit on the darkspace shield 164 so that a negative charge builds up there. It is believed that the negative potential could not only repel further electrons from being deposited, but also confine the electrons in the main plasma area, thus reducing the electron loss, sustaining low-pressure sputtering, and increasing the plasma density, if desired.

The coil 151 is carried on the shield 164 by a plurality of coil standoffs 180 which electrically insulate the coil 151 from the supporting shield 164. In addition, the standoffs 180 have labyrinthine passageways which permit repeated deposition of conductive materials from the target 110 onto the coil standoffs 180 while preventing the formation of a complete conducting path of deposited material from the coil 151 to the shield 164 which could short the coil 151 to the shield 164 (which is typically at ground).

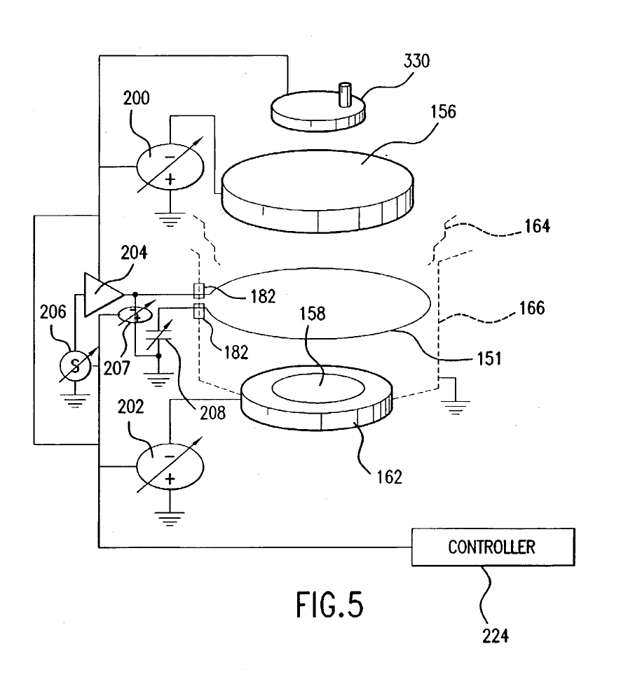

To enable use of the coil as a circuit path, RF power is passed through the vacuum chamber walls and through the shield 164 to ends of the coil 151. Vacuum feedthroughs (not shown) extend through the vacuum chamber wall to provide RF current from a generator preferably located outside the vacuum pressure chamber. RF power is applied through the shield 164 to the coil 151 by feedthrough standoffs 182 (FIG. 5), which like the coil standoffs 180, have labyrinthine passageways to prevent formation of a path of deposited material from the coil 151 to the shield 164 which could short the coil 151 to the shield 164.

The plasma darkspace shield 164 is generally cylindrically-shaped. The plasma chamber shield 166 is generally bowl-shaped and includes a generally cylindrically shaped, vertically oriented wall 190 to which the standoffs 180 and 182 are attached to insulatively support the coil 151.

FIG. 5 is a schematic representation of the electrical connections of the plasma generating apparatus of the illustrated embodiment. To attract the ions generated by the plasma, the target 156 is preferably negatively biased by a variable DC power source 200 at a DC power of 1-40 kW, for example. The source 200 negatively biases the target 156 to about −400 to −600 VDC with respect to the chamber shield 166 to ignite and maintain the plasma. A target power of between 1 and 5 kW is typically used to ignite the plasma while a power of greater than 10 kW is preferred for the SIP sputtering described here. For example, a target power of 24 kW may be used to deposit tantalum nitride by SIP sputtering and a target power of 20 kW may be used to deposit tantalum by SIP sputtering. During ICP resputtering the target power may be reduced to 100-200 watts, for example to maintain plasma uniformity. Alternatively, the target power may be maintained at a high level if target sputtering during ICP resputtering is desired, or may be turned off entirely, if desired.

The pedestal 162 and hence the wafer 158 may be left electrically floating, but a negative DC self-bias may nonetheless develop on it, Alternatively, the pedestal 162 may be negatively biased by a source 202 at −30 v DC to negatively bias the substrate 158 to attract the ionized deposition material to the substrate. Other embodiments may apply an RF bias to the pedestal 162 to further control the negative DC bias that develops on it. For example, the bias power supply 202 may be an RF power supply operating at 13.56 MHz. It may be supplied with RF power in a range of 10 watts to 5 kW, for example, a more preferred range being 150 to 300 W for a 200 mm wafer in SIP deposition.

One end of the coil 151 is insulatively coupled through the shield 166 by a feedthrough standoff 182 to an RF source such as the output of an amplifier and matching network 204. The input of the matching network 204 is coupled to an RF generator 206, which provides RF power at approximately 1 or 1.5 kW watts for ICP plasma generation for this embodiment. For example, a power of 1.5 kW for tantalum nitride deposition and a power of 1 kW for tantalum deposition is preferred. A preferred range is 50 watts to 10 kW. During SIP deposition, the RF power to the coil may be turned off if desired. Alternatively, RF power may be supplied during SIP deposition if desired.

The other end of the coil 151 is also insulatively coupled through the shield 166 by a similar feedthrough standoff 182 to ground, preferably through a blocking capacitor 208 which may be a variable capacitor, to support a DC bias on the coil 151. The DC bias on the coil 151 and hence the coil sputtering rate may be controlled through a DC power source 209 coupled to the coil 151, as described in U.S. Pat. No. 6,375,810. Suitable DC power ranges for ICP plasma generation and coil sputtering include 50 watts to 10 kWatts. A preferred value is 500 watts during coil sputtering. DC power to the coil 151 may be turned off during SIP deposition, if desired.

The above-mentioned power levels may vary of course, depending upon the particular application. A computer-based controller 224 may be programmed to control the power levels, voltages, currents and frequencies of the various sources in accordance with the particular application.

The RF coil 151 may be positioned relatively low in the chamber so that material sputtered from the coil has a low angle of incidence when striking the wafer. As a consequence, coil material may be deposited preferentially on the upper corners of the holes so as to protect those portions of the hole when the hole bottoms are being resputtered by the ICP plasma. In the illustrated embodiment, it is preferred that the coil be positioned closer to the wafer than to the target when the primary function of the coil is to generate a plasma to resputter the wafer and to provide the protective coating during resputtering. For many applications, it is believed that a coil to wafer spacing of 0 to 500 mm will be appropriate. It is appreciated however that the actual position will vary, depending upon the particular application. In those applications in which the primary function of the coil is to generate a plasma to ionize deposition material, the coil may be positioned closer to the target. Also, as set forth in greater detail in copending application Ser. No. 08/680,335, entitled Sputtering Coil for Generating a Plasma, filed Jul. 10, 1996 (Attorney Docket 1390-CIP/PVD/DV) and assigned to the assignee of the present application, an RF coil may also be positioned to improve the uniformity of the deposited layer with sputtered coil material. In addition, the coil may have a plurality of turns formed in a helix or spiral or may have as few turns as a single turn to reduce complexity and costs and facilitate cleaning.

A variety of coil support standoffs and feedthrough standoffs may be used to insulatively support the coils. Since sputtering, particularly at the high power levels associated with SSS, SIP and ICP, involves high voltages, dielectric isolators typically separate the differently biased parts. As a result, it is desired to protect such isolators from metal deposition.

The internal structure of the standoffs is preferably labyrinthine as described in greater detail in copending application Ser. No. 09/515,880, filed Feb. 29, 2000, entitled “COIL AND COIL SUPPORT FOR GENERATING A PLASMA” and assigned to the assignee of the present application. The coil 151 and those portions of the standoffs directly exposed to the plasma are preferably made of the same material which is being deposited. Hence, if the material being deposited is made of tantalum, the outer portions of the standoffs are preferably made of tantalum as well. To facilitate adherence of the deposited material, exposed surfaces of the metal may be treated by bead blasting which will reduce shedding of particles from the deposited material. Besides tantalum, the coil and target may be made from a variety of deposition materials including copper, aluminum, and tungsten. The labyrinth should be dimensioned to inhibit formation of a complete conducting path from the coil to the shield. Such a conducting path could form as conductive deposition material is deposited onto the coil and standoffs. It should be recognized that other dimensions, shapes and numbers of passageways of the labyrinth are possible, depending upon the particular application. Factors affecting the design of the labyrinth include the type of material being deposited and the number of depositions desired before the standoffs need to be cleaned or replaced. A suitable feedthrough standoff may be constructed in a similar manner except that RF power would be applied to a bolt or other conductive member extending through the standoff.

The coil 151 may have overlapping but spaced ends. In this arrangement, the feedthrough standoffs 182 for each end may be stacked in a direction parallel to the plasma chamber central axis between the vacuum chamber target 156 and the substrate holder 162, as shown in FIG. 4. As a consequence, the RF path from one end of the coil to the other end of the coil can similarly overlap and thus avoid a gap over the wafer. It is believed that such an overlapping arrangement can improve uniformity of plasma generation, ionization and deposition as described in copending application Ser. No. 09/039,695, filed Mar. 16, 1998 and assigned to the assignee of the present application.

The support standoffs 180 may be distributed around the remainder of the coil to provide suitable support. In the illustrated embodiments the coils each have three hub members 504 distributed at 90 degree separations on the outer face of each coil. It should be appreciated that the number and spacing of the standoffs may be varied depending upon the particular application.

The coil 151 of the illustrated embodiments is each made of 2 by ¼ inch heavy duty bead blasted tantalum or copper ribbon formed into a single turn coil. However, other highly conductive materials and shapes may be utilized. For example, the thickness of the coil may be reduced to 1/16 inch and the width increased to 2 inches. Also, hollow tubing may be utilized, particularly if water cooling is desired.

The appropriate RF generators and matching circuits are components well known to those skilled in the art. For example, an RF generator such as the ENI Genesis series which has the capability to frequency hunt for the best frequency match with the matching circuit and antenna is suitable. The frequency of the generator for generating the RF power to the coil is preferably 2 MHz but it is anticipated that the range can vary at other A.C. frequencies such as, for example, 1 MHz to 200 MHz and non-RF frequencies. These components may be controlled by the programmable controller 224 as well.

The target 156 includes an aluminum or titanium backing plate 230 to which is soldered or diffusion bonded a target portion 232 of the metal to be deposited such as tantalum or copper. A flange 233 of the backing plate 230 rests on and is vacuum sealed through a polymeric target O-ring 234 to the target isolator 154, which is preferably composed of a ceramic such as alumina. The target isolator 154 rests on and is vacuum sealed through an adaptor O-ring 235 to the chamber 152, which in fact may be an aluminum adaptor sealed to the main chamber body.

A metal clamp ring 236 has on its inner radial side an upwardly extending annular rim 237. Bolts or other suitable fasteners fix the metal clamp ring 236 to an inwardly extending ledge 238 of the chamber 152 and capture a flange 239 of the chamber shield 166. Thereby, the chamber shield 166 is mechanically and electrically connected to the grounded chamber 152.

Copending application Ser. No. 09/414,614, filed Oct. 8, 1999 and entitled “Self-ionized Plasma for Sputtering Copper” (Attorney Docket No. 3920) and assigned to the assignee of the present application, describes one example of a suitable construction of the shields of the chamber. As described in greater detail therein, the shield isolator 168 freely rests on the clamp ring 236 and may be machined from a ceramic material such as alumina. It is compact but has a relatively large height of approximately 165 mm compared to a smaller width to provide strength during the temperature cycling of the reactor. The lower portion of the shield isolator 168 has an inner annular recess fitting outside of the rim 237 of the clamp ring 236. The rim 237 not only acts to center inner diameter of the shield isolator 168 with respect to the clamp ring 236 but also acts as a barrier against any particles generated at the sliding surface 250 between the ceramic shield isolator 168 and the metal ring clamp 236 from reaching the main processing area.

A flange 251 of the darkspace shield 164 freely rests on the shield isolator 168 and has a tab or rim 252 on its outside extending downwardly into an annular recess formed at the upper outer corner of the shield isolator 168. Thereby, the tab 252 centers the darkspace shield 164 with respect to the target 156 at the outer diameter of the shield isolator 168. The shield tab 252 is separated from the shield isolator 168 by a narrow gap which is sufficiently small to align the plasma dark spaces but sufficiently large to prevent jamming of the shield isolator 168, and the darkspace shield 251 rests on the shield isolator 168 in a sliding contact area 253 inside and above the tab 252.

A narrow channel 254 is formed between a head 255 of the darkspace shield 164 and the target 156. It has a width of about 2 mm to act as a plasma dark space. The narrow channel 254 continues in a path extending even more radially inward than illustrated past a downwardly projecting ridge 256 of the backing plate flange 234 to an upper back gap 260 between the shield head 255 and the target isolator 154. The structure of these elements and their properties are similar to those disclosed by Tang et al. in U.S. patent application 09/191,253, filed Oct. 30, 1998. The upper back gap 260 has a width of about 1.5 mm at room temperature. When the shield elements are temperature cycled, they tend to deform. The upper back gap 260, having a smaller width than the narrow channel 254 next to the target 156, is sufficient to maintain a plasma dark space in the narrow channel 254. The back gap 260 continues downwardly into a lower back gap 262 between the shield isolator 168 and the ring clamp 236 on the inside and the chamber body 152 on the outside. The lower back gap 262 serves as a cavity to collect ceramic particles generated at the sliding surfaces 250, 253 between the ceramic shield isolator 168 and the clamp ring 236 and the darkspace shield 164. The shield isolator 168 additionally includes a shallow recess 264 on its upper inner corner to collect ceramic particles from the sliding surface 253 on its radially inward side.

The darkspace shield 164 includes a downwardly extending, wide upper cylindrical portion 288 extending downwardly from the flange 251 and connected on its lower end to a narrower lower cylindrical portion 290 through a transition portion 292. Similarly, the chamber shield 166 has an wider upper cylindrical portion 294 outside of and thus wider than the upper cylindrical portion of the darkspace shield 164. The grounded upper cylindrical portion 294 is connected on its upper end to the grounded shield flange 250 and on its lower end to a narrowed lower cylindrical portion 296 through a transition portion 298 that approximately extends radially of the chamber. The grounded lower cylindrical portion 296 fits outside of and is thus wider than the darkspace lower cylindrical portion 290; but it is smaller than the darkspace upper cylindrical portion 164 by a radial separation of about 3 mm. The two transition portions 292, 298 are both vertically and horizontally offset. A labyrinthine narrow channel 300 is thereby formed between the darkspace and chamber shields 164, 166 with the offset between the grounded lower cylindrical portion 296 and darkspace upper cylindrical portion 164 assuring no direct line of sight between the two vertical channel portions. A purpose of the channel 300 is to electrically isolate the two shields 164, 166 while protecting the clamp ring 236 and the shield isolator 168 from copper deposition.

The lower portion of the channel 300 between the lower cylindrical portions 290, 296 of the shields 164, 166 has an aspect ratio of 4:1 or greater, preferably 8:1 or greater. The lower portion of the channel 300 has an exemplary width of 0.25 cm and length of 2.5 cm, with preferred ranges being 0.25 to 0.3 cm and 2 to 3 cm. Thereby, any deposition material ions and scattered deposition material atoms penetrating the channel 300 are likely to have to bounce several times from the shields and at least stopped by the upper grounded cylindrical portion 294 before they can find their way further toward the clamp ring 236 and the shield isolator 168. Any one bounce is likely to result in the ion being absorbed by the shield. The two adjacent 90 degree turns or bends in the channel 300 between the two transition portions 292, 298 further isolate the shield isolator 168 from the plasma. A similar but reduced effect could be achieved with 60 degree bends or even 45 degree bends but the more effective 90 degree bends are easier to form in the shield material. The 90 degree turns are much more effective because they increase the probability that deposition particles coming from any direction will have at least one high angle hit and thereby lose most their energy to be stopped by the upper grounded cylindrical portion 294. The 90 degree turns also shadow the clamp ring 236 and shield isolator 168 from being directly irradiated by deposition particles. It is believed that metal preferentially deposits on the horizontal surface at tie bottom of the darkspace transition portion 292 and on the vertical upper grounded cylindrical portion 294, both at the end of one of the 90 degree turns. Also, the convolute channel 300 collects ceramic particles generated from the shield isolator 168 during processing on the horizontal transition portion 298 of the chamber shield 166. It is likely that such collected particles are pasted by metal also collected there.

Returning to the large view of FIG. 4, the lower cylindrical portion 296 of the chamber shield 166 continues downwardly to well in back of the top of the pedestal 162 supporting the wafer 158. The chamber shield 166 then continues radially inwardly in a bowl portion 302 and vertically upwardly in an innermost cylindrical portion 151 to approximately the elevation of the wafer 158 but spaced radially outside of the pedestal 162.

The shields 164, 166 are typically composed of stainless steel, and their inner sides may be bead blasted or otherwise roughened to promote adhesion of the material sputter deposited on them. At some point during prolonged sputtering, however, the deposited material builds up to a thickness that it is more likely to flake off, producing deleterious particles. Before this point is reached, the shields should be cleaned or more likely replaced with fresh shields. However, the more expensive isolators 154, 168 do not need to be replaced in most maintenance cycles. Furthermore, the maintenance cycle is determined by flaking of the shields, not by electrical shorting of the isolators.

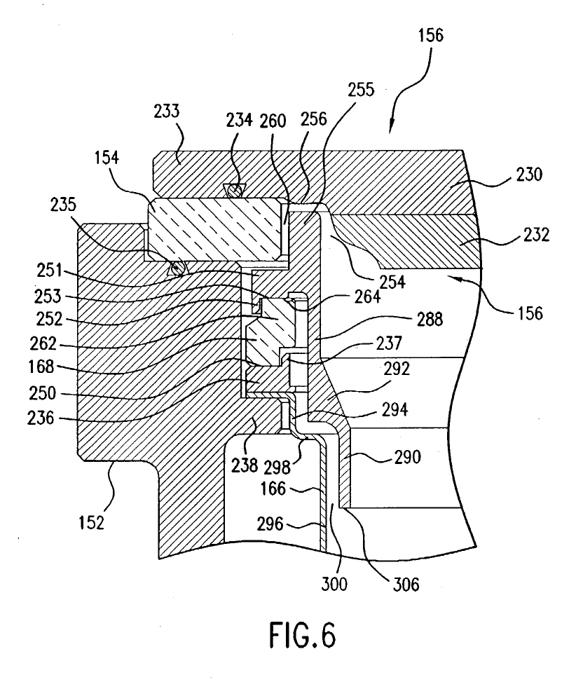

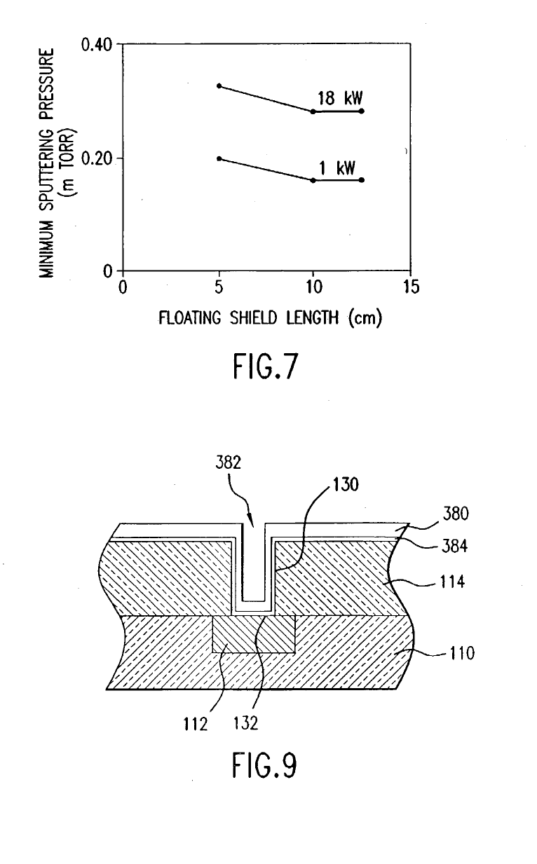

As mentioned, the darkspace shield 164, if floating can accumulate some electron charge and builds up a negative potential. Thereby, it repels further electron loss to the darkspace shield 164 and thus confines the plasma nearer the target 156. Ding et al. have disclosed a similar effect with a somewhat similar structure in U.S. Pat. No. 5,736,021. However, the darkspace shield 164 of FIG. 6 has its lower cylindrical portion 290 extending much further away from the target 156 than does the corresponding part of Ding et al., thereby confining the plasma over a larger volume. However, the darkspace shield 164 electrically shields the chamber shield 166 from the target 156 so that is should not extend too far away from the target 156. If it is too long, it becomes difficult to strike the plasma; but, if it is too short, electron loss is increased so that the plasma cannot be sustained at lower pressure and the plasma density falls. An optimum length has been found at which the bottom tip 306 of the darkspace shield 166, as shown in FIG. 6, is separated 6 cm from the face of the target 156 with a total axial length of the darkspace shield 166 being 7.6 cm. Three different darkspace shields have been tested for the minimum pressure at which copper sputtering is maintained. The results are shown in FIG. 7 for 1 kW and 18 kW of target power. The abscissa is expressed in terms of total shield length, the separation between shield tip 164 and target 156 being 1.6 cm less. A preferred range for the separation is 5 to 7 cm, and that for the length is 6.6 to 8.6 cm. Extending the shield length to 10 cm reduces the minimum pressure somewhat but increases the difficulty of striking the plasma.

Referring again to FIG. 4, a gas source 314 supplies a sputtering working gas, typically the chemically inactive noble gas argon, to the chamber 152 through a mass flow controller 316. The working gas can be admitted to the top of the chamber or, as illustrated, at its bottom, either with one or more inlet pipes penetrating apertures through the bottom of the shield chamber shield 166 or through a gap 318 between the chamber shield 166, the wafer clamp 160, and the pedestal 162. A vacuum pump system 320 connected to the chamber 152 through a wide pumping port 322 maintains the chamber at a low pressure. Although the base pressure can be held to about 10⁻⁷ Torr or even lower, the pressure of the working gas is typically maintained at between about 1 and 1000 milliTorr in conventional sputtering and to below about 5 milliTorr in SIP sputtering. The computer-based controller 224 controls the reactor including the DC target power supply 200, the bias power supply 202, and the mass flow controller 316.

To provide efficient sputtering, a magnetron 330 is positioned in back of the target 156. It has opposed magnets 332, 334 connected and supported by a magnetic yoke 336. The magnets create a magnetic field adjacent the magnetron 330 within the chamber 152. The magnetic field traps electrons and, for charge neutrality, the ion density also increases to form a high-density plasma region 338. The magnetron 330 is usually rotated about the center 340 of the target 156 by a motor-driven shaft 342 to achieve full coverage in sputtering of the target 156. To achieve a high-density plasma 338 of sufficient ionization density to allow sustained self-sputtering of copper, the power density delivered to the area adjacent the magnetron 330 is preferably made high. This can be achieved, as described by Fu in the above cited patents, by increasing the power level delivered from the DC power supply 200 and by reducing the area of magnetron 330, for example, in the shape of a triangle or a racetrack. A 60 degree triangular magnetron, which is rotated with its tip approximately coincident with the target center 340, covers only about ⅙ of the target at any time. Coverage of ¼ is the preferred maximum in a commercial reactor capable of SIP sputtering.

To decrease the electron loss, the inner magnetic pole represented by the inner magnet 332 and magnetic pole face should have no significant apertures and be surrounded by a continuous outer magnetic pole represented by the outer magnets 334 and pole face. Furthermore, to guide the ionized sputter particles to the wafer 158, the outer pole should produce a much higher magnetic flux than the inner pole. The extending magnetic field lines trap electrons and thus extend the plasma closer to the wafer 158. The ratio of magnetic fluxes should be at least 150% and preferably greater than 200%. Two embodiments of Fu's triangular magnetron have 25 outer magnets and 6 or 10 inner magnets of the same strength but opposite polarity. Although depicted in combination with a planar target surface, it is appreciated that a variety of unbalanced magnetrons may be used with a variety of target shapes to generate self ionzed plasmas.

When the argon is admitted into the chamber, the DC voltage difference between the target 156 and the chamber shield 166 ignites the argon into a plasma, and the positively charged argon ions are attracted to the negatively charged target 156. The ions strike the target 156 at a substantial energy and cause target atoms or atomic clusters to be sputtered from the target 156. Some of the target particles strike the wafer 158 and are thereby deposited on it, thereby forming a film of the target material. In reactive sputtering of a metallic nitride, nitrogen is additionally admitted into the chamber from a source 343, and it reacts with the sputtered metallic atoms to form a metallic nitride on the wafer 158.

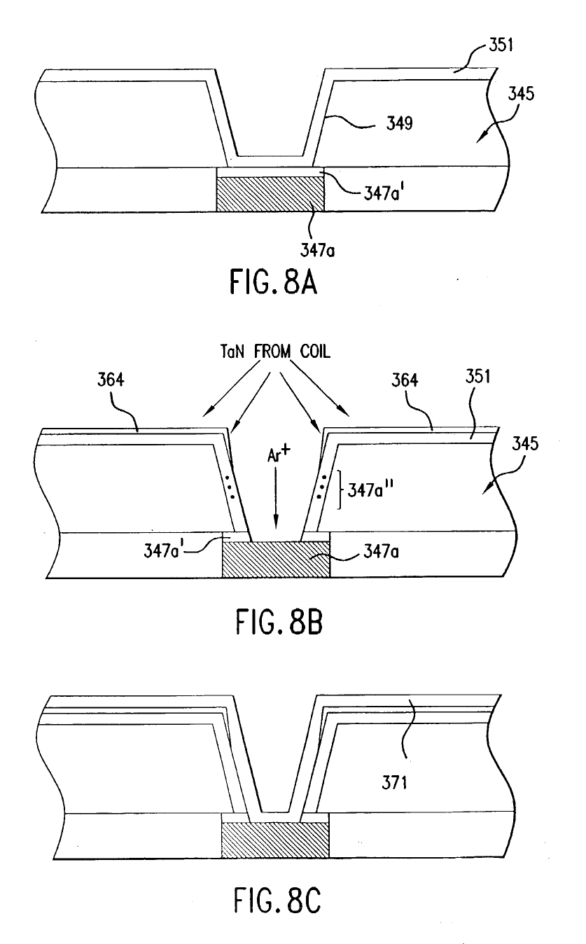

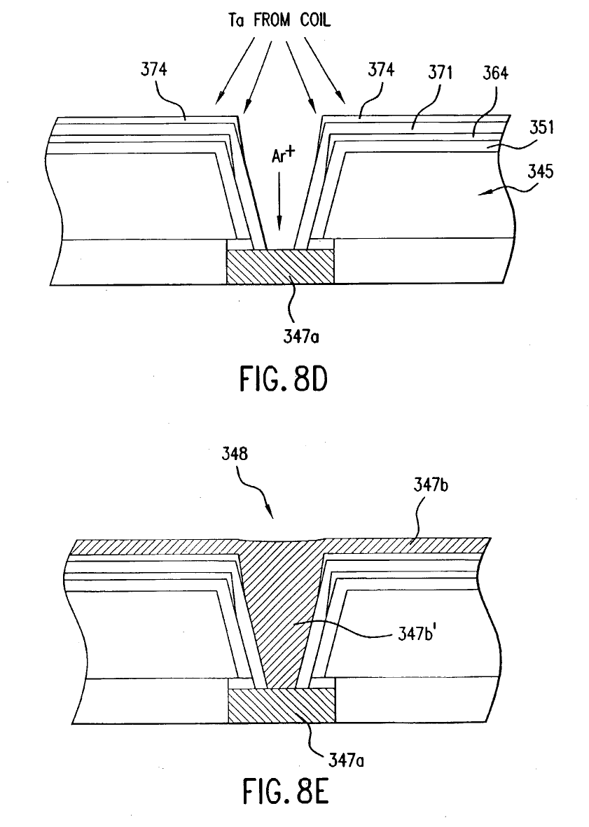

FIGS. 8A-E show sequential cross-sectional views of the formation of liner layers in accordance with a one aspect of the present inventions. With reference to FIG. 8A, an interlayer dielectric 345 (e.g. silicon dioxide) is deposited over a first metal layer (e.g., a first copper layer 347a) of an interconnect 348 (FIG. 8E). A via 349 then is etched in the interlayer dielectric 345 to expose the first copper layer 347a. The first metal layer may be deposited using CVD,PVD, electroplating or other such well known metal deposition techniques, and it is connected, via contacts, through a dielectric layer, to devices formed in the underlying semiconductor wafer. If the first copper layer 347a is exposed to oxygen, such as when the wafer is moved from an etching chamber in which the oxide overlaying the first copper layer is etched to create apertures for creation of vias between the first copper layer and a second to be deposited metal layer, it can readily form an insulating/high resistance copper oxide layer 347a′ thereon. Accordingly, to reduce the resistance of the copper interconnect 348, any copper oxide layer 347a′ and any processing residue within the via 349 may be removed.

A barrier layer 351 may be deposited (e.g., within the sputtering chamber 152 of FIG. 2) over the interlayer dielectric 345 and over the exposed first copper layer 347a prior to removing the copper oxide layer 347a′. The barrier layer 351, preferably comprising tantalum, tantalum nitride, titanium nitride, tungsten or tungsten nitride prevents subsequently deposited copper layers from incorporating in and degrading the interlayer dielectric 345 (as previously described).

If, for example, the sputtering chamber 152 is configured for deposition of tantalum nitride layers, a tantalum target 156 is employed. Typically, both argon and nitrogen gas are flowed into the sputtering chamber 152 through the gas inlet 360 (multiple inlets, one for each gas, may be used), while a power signal is applied to the target 156 via the DC power supply 200. Optionally, a power signal may also be applied to the coil 151 via the first RF power supply 206. During steady-state processing, nitrogen may react with the tantalum target 156 to form a nitride film on the tantalum target 156 so that tantalum nitride is sputtered therefrom. Additionally, non-nitrided tantalum atoms are also sputtered from the target, which atoms can combine with nitrogen to form tantalum nitride in flight or on a wafer (not shown) supported by the pedestal 162.

In operation, a throttle valve operatively coupled to the exhaust outlet 362 is placed in a mid-position in order to maintain the deposition chamber 152 at a desired low vacuum level of about 1×10⁻⁸ torr prior to introduction of the process gas(es) into the chamber. To commence processing within the sputtering chamber 152, a mixture of argon and nitrogen gas is flowed into the sputtering chamber 152 via a gas inlet 360. After the gas stabilizes at a pressure of about 10-100 milliTorr (preferably 10-60 millitorr, and more preferably 15-30 milliTorr), DC power is applied to the tantalum target 156 via the DC power supply 200 (while the gas mixture continues to flow into the sputtering chamber 152 via the gas inlet 360 and is pumped therefrom via the pump 37). The DC power applied to the target 156 causes the argon/nitrogen gas mixture to form an SIP plasma and to generate argon and nitrogen ions which are attracted to, and strike the target 156 causing target material (e.g., tantalum and tantalum nitride) to be ejected therefrom. The ejected target material travels to and deposits on the wafer 158 supported by the pedestal 162. In accordance with the SIP process, the plasma created by the unbalanced magnetron ionizes a portion of the sputtered tantalum and tantalum nitride. By adjusting the RF power signal applied to the substrate support pedestal 162, a negative bias can be created between the substrate support pedestal 162 and the plasma. The negative bias between the substrate support pedestal 162 and the plasma causes tantalum ions, tantalum nitride ions and argon ions to accelerate toward the pedestal 162 and any wafer supported thereon. Accordingly, both neutral and ionized tantalum nitride may be deposited on the wafer, providing good sidewall and upper sidewall coverage in accordance with SIP sputtering. In addition, particularly if RF power is optionally applied to the ICP coil, the wafer may be sputter-etched by the argon ions at the same time the tantalum nitride material from the target 156 deposits on the wafer (i.e., simultaneous deposition/sputter-etching)

Following deposition of the barrier layer 351, the portion of the barrier layer 351 at the bottom of the via 349, and the copper oxide layer 347a′ (and any processing residue) thereunder, may be sputter-etched or resputtered via an argon plasma as shown in FIG. 8B, if thinning or elimination of the bottom is desired. The argon plasma is preferably generated in this step primarily by applying RF power to the ICP coil. Note that during sputter-etching within the sputtering chamber 152 (FIG. 2) in this embodiment, the power applied to the target 156 is preferably either removed or is reduced to a low level (e.g., 100 or 200 W) so as to inhibit or prevent significant deposition from the target 156. A low target power level, rather than no target power, can provide a more uniform plasma and is presently preferred.

ICP argon ions are accelerated toward the barrier layer 351 via an electric field (e.g., the RF signal applied to the substrate support pedestal 162 via the second RF power supply 41 of FIG. 2 which causes a negative self bias to form on the pedestal), strike the barrier layer 351, and, due to momentum transfer, sputter the barrier layer material from the base of the via aperture and redistribute it along the portion of the barrier layer 351 that coats the sidewalls of the via 349. The argon ions are attracted to the substrate in a direction substantially perpendicular thereto. As a result, little sputtering of the via sidewall, but substantial sputtering of the via base, occurs. To facilitate resputtering, the bias applied to the pedestal and the wafer may be 400 watts, for example.

The particular values of the resputtering process parameters may vary depending upon the particular application. Copending or issued applications Ser. Nos. 08/768,058; 09/126,890; 09/449,202; 09/846,581; 09/490,026; and 09/704,161, describe resputtering processes and are incorporated herein by reference in their entireties.

In accordance with another aspect of the present inventions, the ICP coil 151 may be formed of liner material such as tantalum in the same manner as the target 156 and sputtered to deposit tantalum nitride onto the wafer while the via bottoms are resputtered. Because of the relatively low pressure during the resputtering process, the ionization rate of the deposition material sputtered from the coil 151 is relatively low. Hence, the sputtered material deposited onto the wafer is primarily neutral material. In addition, the coil 151 is placed relatively low in the chamber, surrounding and adjacent to the wafer.

Consequently, the trajectory of the material sputtered from the coil 151 tends to have a relatively small angle of incidence. Hence, the sputtered material from the coil 151 tends to deposit in a layer 364 on the upper surface of the wafer and around the openings of the holes or vias in the wafer rather than deep into the wafer holes. This deposited material from the coil 151 may be used to provide a degree of protection from resputtering so that the barrier layer is thinned by resputtering primarily at the bottom of the holes rather than on the sidewalls and around the hole openings where thinning of the barrier layer may not be desired.

Once the barrier layer 351 has been sputter-etched from the via base, the argon ions strike the copper oxide layer 347a′, and the oxide layer is sputtered to redistribute the copper oxide layer material from the via base, some or all of the sputtered material being deposited along the portion of the barrier layer 351 that coats the sidewalls of the via 349. Copper atoms 347a″, as well, coat the barrier layer 351 and 364 disposed on the sidewalls of the via 349. However, because the originally deposited barrier layer 351 along with that redistributed from the via base to via sidewall is a diffusion barrier to the copper atoms 347a″, the copper atoms 347a″ are substantially immobile within the barrier layer 351 and are inhibited from reaching the interlayer dielectric 345. The copper atoms 347a″ which are deposited onto the sidewall, therefore, generally do not generate via-to-via leakage currents as they would were they redistributed onto an uncoated sidewall.

Thereafter, a second liner layer 371 of a second material such as tantalum may be deposited (FIG. 8C) on the previous barrier layer 351 in the same chamber 152 or a similar chamber having both an SIP and ICP capabilities. A tantalum liner layer provides good adhesion between the underlying tantalum nitride barrier layer and a subsequently deposited metal interconnect layer of a conductor such as copper. The second liner layer 371 may be deposited in the same manner as the first liner layer 351. That is, the tantalum liner 371 may be deposited in a first SIP step in which the plasma is generated primarily by the target magnetron 330. However, nitrogen is not admitted so that tantalum rather than tantalum nitride is deposited. In accordance with SIP sputtering, good sidewall and upper sidewall coverage may be obtained. RF power to the ICP coil 151 may be reduced or eliminated, if desired.

Following deposition of the tantalum liner layer 371, the portion of the liner layer 371 at the bottom of the via 349 (and any processing residue) thereunder, may be sputter-etched or resputtered via an argon plasma in the same manner as the bottom of the liner layer 351, as shown in FIG. 8D, if thinning or elimination of the bottom is desired. The argon plasma is preferably generated in this step primarily by applying RF power to the ICP coil. Again, note that during sputter-etching within the sputtering chamber 152 (FIG. 2), the power applied to the target 156 is preferably either removed or is reduced to a low level (e.g., 500 W) so as to inhibit or prevent significant deposition from the target 156 during thinning or elimination of the bottom coverage of the second liner layer 371. In addition, the coil 151 is preferably sputtered to deposit liner material 374 while the argon plasma resputters the layer bottom to protect the liner sidewalls and upper portions from being thinned substantially during the bottom portion resputtering.

In the above described embodiment, SIP deposition of target material on the sidewalls of the vias occurs primarily in one step and ICP resputtering of the via bottoms and ICP deposition of coil 151 material occurs primarily in a subsequently step. It is appreciated that deposition of both target material and coil material on the sidewalls of the via 349 can occur simultaneously, if desired. It is further appreciated that ICP sputter-etching of the deposited material at the bottom of the via 349 can occur simultaneously with the deposition of target and coil material on the sidewalls, if desired. Simultaneous deposition/sputter-etching may be performed with the chamber 152 of FIG. 2 by adjusting the power signals applied to the coil 151, the target 156 and the pedestal 162. Because the coil 151 can be used to maintain the plasma, the plasma can sputter a wafer with a low relative bias on the wafer (less than that needed to sustain the plasma). Once the sputtering threshold has been reached, for a particular wafer bias the ratio of the RF power applied to the wire coil 151 (“RF coil power”) as compared to the DC power applied to the target 156 (“DC target power”) affects the relationship between sputter-etching and deposition. For instance, the higher the RF:DC power ratio the more sputter-etching will occur due to increased ionization and subsequent increased ion bombardment flux to the wafer. Increasing the wafer bias (e.g., increasing the RF power supplied to the support pedestal 162) will increase the energy of the incoming ions which will increase the sputtering yield and the etch rate. For example, increasing the voltage level of the RF signal applied to the pedestal 162 increases the energy of the ions incident on the wafer, while increasing the duty cycle of the RF signal applied to the pedestal 162 increases the number of incident ions.

Therefore, both the voltage level and the duty cycle of the wafer bias can be adjusted to control sputtering rate. In addition, keeping the DC target power low will decrease the amount of barrier material available for deposition. A DC target power of zero will result in sputter-etching only. A low DC target power coupled with a high RF coil power and wafer bias can result in simultaneous via sidewall deposition and via bottom sputtering. Accordingly, the process may be tailored for the material and geometries in question. For a typical 3:1 aspect ratio via on a 200 mm wafer, using tantalum or tantalum nitride as the barrier material, a DC target power of 500 W to 1 kW, at an RF coil power of 2 to 3 kW or greater, with a wafer bias of 250 W to 400 W or greater applied continuously (e.g., 100% duty cycle) can result in barrier deposition on the wafer sidewalls and removal of material from the via bottom. The lower the DC target power, the less material will be deposited on the sidewalls. The higher the DC target power, the more RF coil power and/or wafer bias power is needed to sputter the bottom of the via. A 2 kW RF coil power level on the coil 151 and a 250 W RF wafer power level with 100% duty cycle on the pedestal 162, for example may be used for simultaneous deposition/sputter-etching. It may be desirable to initially (e.g., for several seconds or more depending on the particular geometries/materials in question) apply no wafer bias during simultaneous deposition/sputter-etching to allow sufficient via sidewall coverage to prevent contamination of the sidewalls by material sputter-etched from the via bottom.

For instance, initially applying no wafer bias during simultaneous deposition/sputter-etching of the via 349 can facilitate formation of an initial barrier layer on the sidewalls of the interlayer dielectric 345 that inhibits sputtered copper atoms from contaminating the interlayer dielectric 345 during the remainder of the deposition/sputter-etching operation. Alternatively, deposition/sputter-etching may be performed “sequentially” within the same chamber or by depositing the barrier layer 351 within a first processing chamber and by sputter-etching the barrier layer 351 and copper oxide layer 347a′ within a separate, second processing chamber (e.g., a sputter-etching chamber such as Applied Materials' Preclean II chamber).

Following deposition of the second liner layer 371 and thinning of the bottom coverage, a second metal layer 347b is deposited (FIG. 8E) to form the copper interconnect 348. The second copper layer 347b may deposited either conformally or so as to form a copper plug 347b′ as shown in FIG. 8E over the second liner layer 371 and over the portion of the first copper layer 347a exposed at the base of each via. Because the first and second copper layers 347a, 347b are in direct contact, rather than in contact through the barrier layer 351 or the second liner layer 371, the resistance of the copper interconnect 348 can be lower as can via-to-via leakage currents as well.

If the interconnect is formed of a different conductor metal than the liner layer or layers, the interconnect layer may be deposited in a sputter chamber having a target of the different conductor metal. The sputter chamber may be an SIP type or an ICP type. The metal interconnect may be deposited by other methods in other types of chambers and apparatus including CVD and electrochemical plating.

Still further, in accordance with another aspect of the present inventions, the interconnect layer or layers may be deposited in a sputter chamber similar to the chamber 152 which generates both SIP and ICP plasmas. If deposited in a chamber such as the chamber 152, the target 156 would be formed of the deposition material, such as copper, for example. In addition, the ICP coil 151 may be formed of the same deposition material as well, particularly if coil sputtering is desired for some or all of the interconnect metal deposition.

As previously mentioned, the illustrated chamber 152 is capable of self-ionized sputtering of copper including sustained self-sputtering. In this case, after the plasma has been ignited, the supply of argon may be cut off in the case of SSS, and the copper ions have sufficiently high density to resputter the copper target with a yield of greater than unity. Alternatively, some argon may continue to be supplied, but at a reduced flow rate and chamber pressure and perhaps with insufficient target power density to support pure sustained self-sputtering but nonetheless with a significant but reduced fraction of self-sputtering. If the argon pressure is increased to significantly above 5 milliTorr, the argon will remove energy from the copper ions, thus decreasing the self-sputtering. The wafer bias attracts the ionized fraction of the copper particle deep into the hole.

However, to achieve deeper hole coating with a partially neutral flux, it is desirable to increase the distance between the target 156 and the wafer 158, that is, to operate in the long-throw mode. In long-throw, the target-to-substrate spacing is typically greater than half the substrate diameter, preferably greater than wafer diameter, more preferably at least 80% of the substrate diameter, and most preferably least 140% of the substrate diameter. The throws mentioned in the examples of the embodiment are referenced to 200 mm wafers. For many applications, it is believed that a target to wafer spacing of 50 to 1000 mm will be approrpriate. Long throw in conventional sputtering reduces the sputtering deposition rate, but ionized sputter particles do not suffer such a large decrease.

The controlled division among self-ionized plasma (SIP) sputtering, inductively coupled plasma (ICP) sputtering and sustained self-sputtering (SSS) allows the control of the distribution between neutral and ionized sputter particles. Such control is particularly advantageous for the sputter deposition of a copper seed layer in a high aspect-ratio via hole. The control of the ionization fraction of sputtered is achieved by mixing self-ionized plasma (SIP) sputtering and inductively coupled plasma (ICP) sputtering.

One embodiment of a structure in accordance with the present inventions is a via illustrated in cross-section in FIG. 9. A copper seed layer 380 is deposited in a via hole 382 over the liner layer 384 (which may include one or more barrier and liner layers such as the aforementioned TaN barrier and Ta liner layers) using, for example, the long-throw sputter reactor of FIG. 4 and under conditions promoting combined SIP and ICP and/or alternating SIP and ICP. The SIP-ICP copper layer 380 may be deposited, for example, to a blanket thickness of 50 to 300 nm or more preferably of 80 to 200 nm. The SIP-ICP copper seed layer 380 preferably has a thickness in the range of 2 to 20 nm on the via sidewalls, more preferably 7 to 15 nm. In view of the narrow holes, the sidewall thickness should not exceed 50 nm. The quality of the film is improved by decreasing the pedestal temperature to less than 01 C. and preferably to less than −401 C. so that the coolness afforded by the quick SIP deposition becomes important.

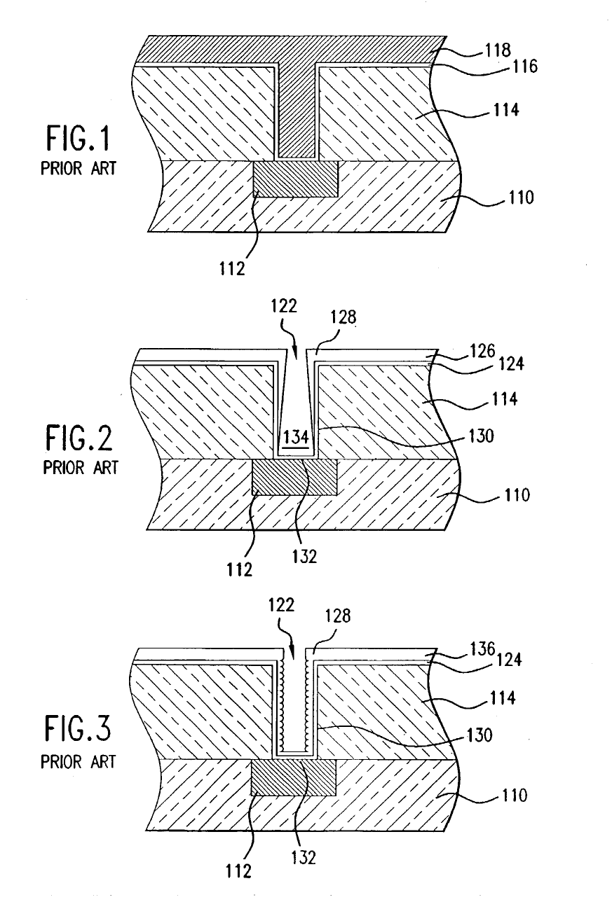

It is believed that the SIP-ICP copper seed layer 380 will have good bottom coverage and enhanced sidewall coverage. After the conformal copper seed layer 380 is deposited, the hole may be filled with a copper layer similar to the copper layer 18, of FIG. 1, preferably by electro-chemical plating using the seed layer 380 as one of the electroplating electrodes. However, the smooth structure of the SIP-ICP copper seed layer 380 also promotes reflow or higher-temperature deposition of copper by standard sputtering or physical vapor deposition (PVD).

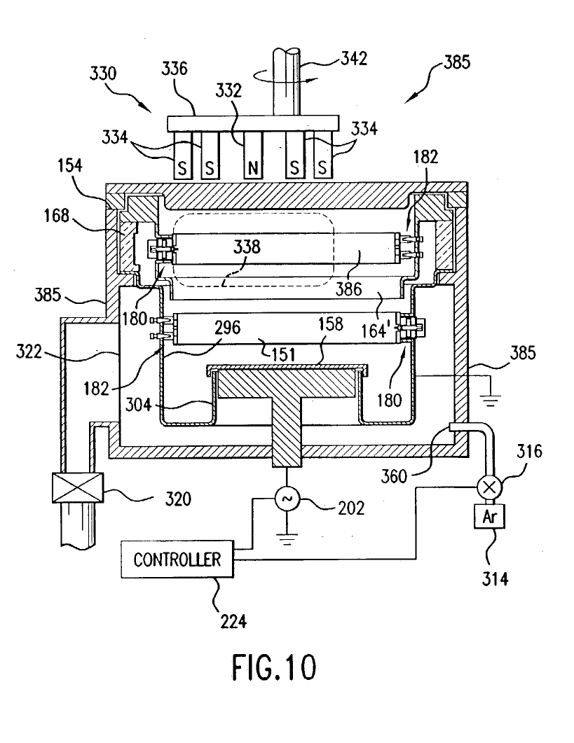

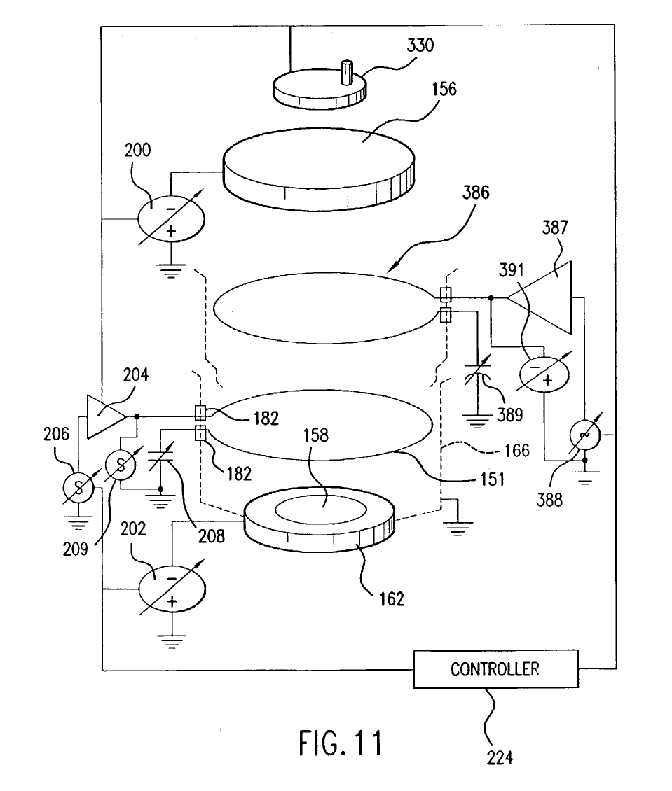

In one embodiment, an SIP-ICP layer may be formed in a process which combines selected aspects of both SIP and ICP deposition techniques in one step, referred to herein generally as an SIP-ICP step. In addition, a reactor 385 in accordance with an alternative embodiment has a second coil 386 in addition to the coil 151 as shown in FIG. 10. In the same manner as the coil 151, one end of the coil 386 is insulatively coupled through a darkspace shield 164′ by a feedthrough standoff 182 to the output of an amplifier and matching network 387 (FIG. 11). The input of the matching network 387is coupled to an RF generator 388. The other end of the coil 386 is insulatively coupled through the shield 164′ by a feedthrough standoff 182 to ground, via a blocking capacitor 389, to provide a DC bias on the coil 386. The DC bias may be controlled by a separate DC source 391.

In an ICP or combined SIP-ICP step, RF energy is applied to one or both of the RF coils 151 and 386 at 1-3 kW and a frequency of 2 Mhz, for example. The coils 151 and 386 when powered, inductively couple RF energy into the interior of the reactor. The RF energy provided by the coils ionizes a precursor gas such as argon to maintain a plasma to ionize sputtered deposition material. However, rather than maintain the plasma at a relatively high pressure, such as 20-60 mTorr typical for high density IMP processes, the pressure is preferably maintained at a substantially lower pressure, such as 2 mTorr, for example. As a consequence, it is believed that the ionization rate within the reactor 150 will be substantially lower than that of the typical high density IMP process.

Furthermore as discussed above, the illustrated reactor 150 is also capable of self-ionized sputtering in a long-throw mode. As a consequence, deposition material may be ionized not only as a result of the low pressure plasma maintained by the RF coil or coils, but also by the plasma self-generated by the DC magnetron sputtering of the target. It is believed that the combined SIP and ICP ionization processes can provide sufficient ionized material for good bottom and bottom corner coverage. However, it is also believed that the lower ionization rate of the low pressure plasma provided by the RF coils 151 and 386 allows sufficient neutral sputtered material to remain un-ionized so as to be deposited on the upper sidewalls by the long-throw capability of the reactor. Thus, it is believed that the combined SIP and ICP sources of ionized deposition material can provide both good upper sidewall coverage as well as good bottom and bottom corner coverage. In another embodiment, the power to the coils 151 and 386 may be alternated such that in one step, the power to the upper coil 396 is eliminated or reduced relative to the power applied to the lower coil 151. In this step, the center of the inductively coupled plasma is shifted away from the target and closer to the substrate. Such an arrangement may reduce interaction between the self ionized plasma generated adjacent the target, and the inductively coupled plasma maintained by one or more of the coils. As a consequence, a higher proportion of neutral sputtered material might be maintained.

In a second step, the power may be reversed such that the power to the lower coil 151 is eliminated or reduced relative to the power applied to the upper coil 386. In this step, the center of the inductively coupled plasma may be shifted toward the target and away from the substrate. Such an arrangement may increase the proportion of ionized sputtered material.

In another embodiment, the layer may be formed in two or more steps in which in one step, referred to herein generally as an SIP step, little or no RF power is applied to either coil. In addition, the pressure would be maintained at a relatively low level, preferably below 5 mTorr, and more preferably below 2 mTorr such as at 1 mTorr, for example. Furthermore, the power applied to the target would be relatively high such as in the range of 18-24 kW DC, for example. A bias may also be applied to the substrate support at a power level of 500 watts for example. Under these conditions, it is believed that ionization of the deposition material would occur primarily as a result of (SIP) self-ionization plasma. Combined with the long-throw mode arrangement of the reactor, it is believed that good upper sidewall coverage may be achieved with low overhang. The portion of the layer deposited in this initial step may be in the range of 1000-2000 angstroms, for example.

In a second step, referred to generally herein as an ICP step, and preferably in the same chamber, RF power may be applied to one or both of the coils 151 and 386. In addition, in one embodiment, the pressure may be raised substantially such that a high density plasma may be maintained. For example, the pressure may be raised to 20-60 mTorr, the RF power to the coil raised to a range of 1-3 kW, the DC power to the target reduced to 1-2 kW and the bias to the substrate support reduced to 150 watts. Under these conditions, it is believed the ionization of the deposition material would occur primarily as a result of high-density ICP. As a result, good bottom and bottom comer coverage may be achieved in the second step. Power may be applied to both coils simultaneously or alternatingly, as described above.

After the copper seed layer is sputter deposited by a process combining SIP and ICP, the remainder of the hole may be filled by the same or another process. For example, the remainder of the hole may be filled by electroplating or CVD.

It should be appreciated that the order of the SIP and ICP steps may be reversed and that some RF power may be applied to one or more coils in the SIP step and that some self-ionization may be induced in the ICP step. In addition, sustained self sputtering (SSS) may be induced in one or more steps. Hence, process parameters including pressure, power and target-wafer distance may be varied, depending upon the particular application, to achieve the desired results.

For example, copending application Ser. No. 09/414,614, filed Oct. 8, 1999 describes several experiments in which process parameters were varied to achieve different combinations of SIP and SSS depositions and long throw modes in a reactor not having RF coils. The process conditions described may be applied to a reactor in which an SIP-ICP step, a multi-step including an SIP step and ICP step, or combination thereof is employed.

As described in the Ser. No. 09/414,614 application, several experiments were performed in SIP depositing such a seed layer into a 0.20 μm-wide via hole in 1.2 μm of oxide. With a target-to-substrate spacing of 290 mm, a chamber pressure of less than 0.1 milliTorr (indicating SSS mode) and 14 kW of DC power applied to the target with a 601 triangular magnetron, a deposition producing 0.2 μm of blanket thickness of the copper on top of the oxide produces 18 nm on the via bottom and about 12 nm on the via sidewalls. Deposition times of 30 s and less are typical, When the target power is increased to 18 kw, the bottom coverage increases to 37 nm without a significant change in sidewall thickness. The higher bottom coverage at higher power indicates a higher ionization fraction. For both cases, the deposited copper film is observed to be much smoother than seen for IMP or CVD copper.

The SIP deposition is relatively fast, between 0.5 to 1.0 μm/min in comparison to an IMP deposition rate of no more than 0.2 μm/min. The fast deposition rate results in a short deposition period and, in combination with the absence of argon ion heating, significantly reduces the thermal budget. It is believed that the low-temperature SIP deposition results in a very smooth copper seed layer.

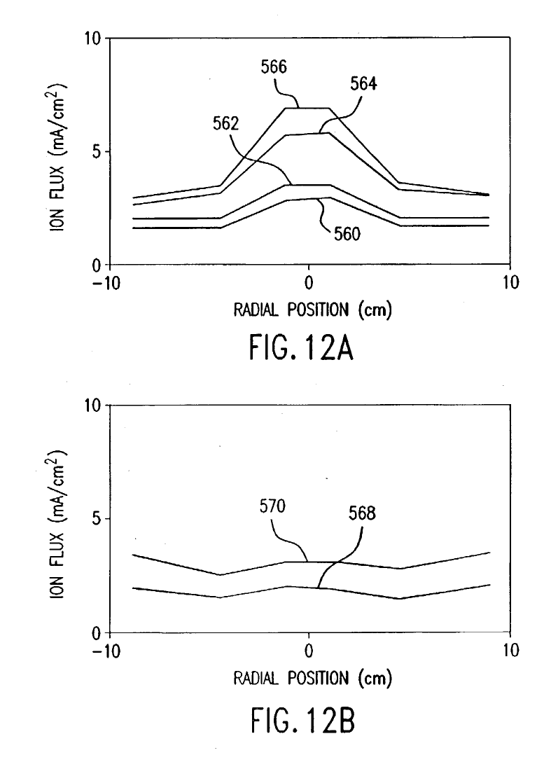

A 290 mm throw was used with the standard triangular magnetron of Fu utilizing ten inner magnets and twenty-five outer ones. The ion current flux was measured as a function of radius from the target center under various conditions. The results are plotted in the graph of FIG. 12A. Curve 560 is measured for 16 kW of target power and 0 milliTorr of chamber pressure. Curves 562, 564, 564 are measured for 18 kW of target power and chamber pressures of 0, 0.2, and 1 milliTorr respectively. These currents correspond to an ion density of between 10¹¹ and 10¹² cm⁻³, as compared to less than 109 cm⁻³ with a conventional magnetron and sputter reactor. The zero-pressure conditions were also used to measure the copper ionization fraction. The spatial dependences are approximately the same with the ionization fraction varying between about 10% and 20% with a direct dependence on the DC target power. The relatively low ionization fraction demonstrate that SIP without long throw would has a large fraction of neutral copper flux which would have the unfavorable deep filling characteristics of conventional PVD. Results indicate that operation at higher power is preferred for better step coverage due to the increased ionization.

The tests were then repeated with the number of inner magnets in the Fu magnetron being reduced to six. That is, the second magnetron had improved uniformity in the magnetic flux, which promotes a uniform sputtered ion flux toward the wafer. The results are plotted in FIG. 12B. Curve 568 displays the ion current flux for 12 kW of target power and 0 milliTorr pressure curve 570, for 18 kW. Curves for 14 kW and 16 kW are intermediate. Thus, the modified magnetron produces a more uniform ion current across the wafer, which is again dependent on the target power with higher power being preferred.

The relatively low ionization fractions of 10% to 20% indicate a substantial flux of neutral copper compared to the 90% to 100% fraction of IMP. While wafer bias can guide the copper ions deep into the holes, long throw accomplishes much the same for the copper neutrals.

A series of tests were used to determine the combined effects of throw and chamber pressure upon the distribution of sputter particles. At zero chamber pressure, a throw of 140 mm produces a distribution of about 451; a throw of 190 mm, about 351; and, a throw of 290 mm, about 251. The pressure was varied for a throw of 190 mm. The central distribution remains about the same for 0, 0.5 and 1 milliTorr. However, the low-level tails are pushed out almost 101 for the highest pressure, indicative of the scattering of some particles. These results indicate that acceptable results are obtained below 5 milliTorr, but a preferred range is less than 2 milliTorr, a more preferred range is less than 1 milliTorr, and a most preferred range is 0.2 milliTorr and less. Also, as expected, the distribution is best for the long throws.

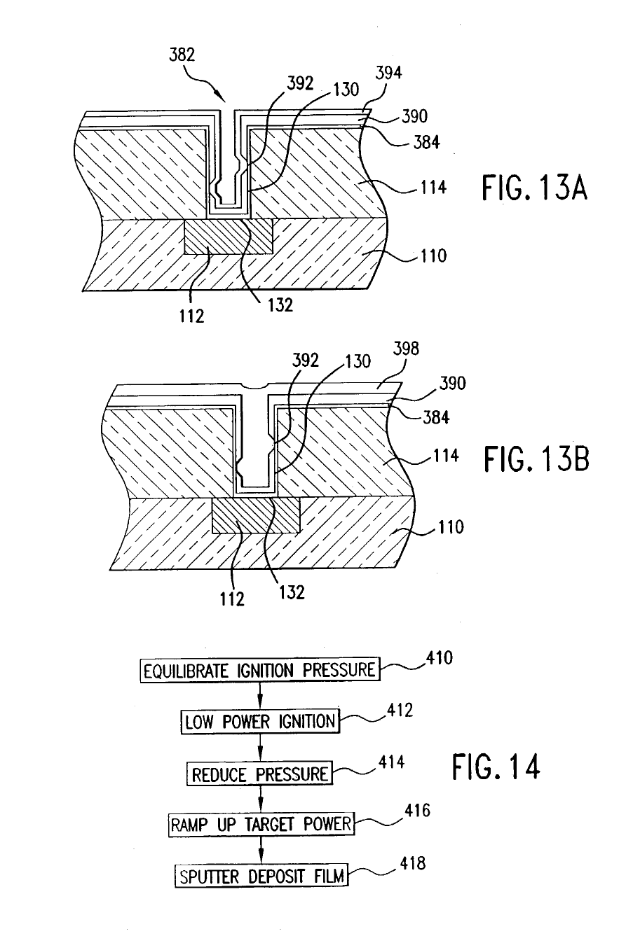

The SIP sidewall coverage may become a problem for very narrow, high-aspect ratio vias. Technology for 0.13 μm vias and smaller is being developed. Below about 100 nm of blanket thickness, the sidewall coverage may become discontinuous. As shown in the cross-sectional view of FIG. 13A, the unfavorable geometry may cause a SIP copper film 390 to be formed as a discontinuous films including voids or other imperfections 392 on the via sidewall 130. The imperfection 392 may be an absence of copper or such a thin layer of copper that it cannot act locally as an electroplating cathode. Nonetheless, the SIP copper film 390 is smooth apart from the imperfections 392 and well nucleated. In these challenging geometries, it is then advantageous to deposit a copper CVD seed layer 394 over the SIP copper nucleation film 390. Since it is deposited by chemical vapor deposition, it is generally conformal and is well nucleated by the SIP copper film 390. The CVD seed layer 394 patches the imperfections 392 and presents a continuous, non-rough seed layer for the later copper electroplating to complete the filling of the hole 382. The CVD layer may be deposited in a CVD chamber designed for copper deposition, such as the CuxZ chamber available from Applied Materials using the previously described thermal process.

Experiments were performed in which 20 nm of CVD copper was deposited on alternatively a SIP copper nucleation layer and an IMP nucleation layer. The combination with SIP produced a relatively smooth CVD seed layer while the combination with IMP produced a much rougher surface in the CVD layer to the point of discontinuity.

The CVD layer 394 may be deposited to a thickness, for example, in the range of 5 to 20 nm. The remainder of the hole may then be filled with copper by other methods. The very smooth seed layer produced by CVD copper on top of the nucleation layer of SIP copper provides for efficient hole filling of copper by electroplating or conventional PVD techniques in the narrow vias being developed. In particular for electroplating, the smooth copper nucleation and seed layer provides a continuous and nearly uniform electrode for powering the electroplating process.

In the filling of a via or other hole having a very high-aspect ratio, it may be advantageous to dispense with the electroplating and instead, as illustrated in the cross-sectional view of FIG. 13B, deposit a sufficiently thick CVD copper layer 398 over the SIP copper nucleation layer 390 to completely fill the via. An advantage of CVD filling is that it eliminates the need for a separate electroplating step. Also, electroplating requires fluid flows which may be difficult to control at hole widths below 0.13 μm.

An advantage of the copper bilayer of this embodiment of the invention is that it allows the copper deposition to be performed with a relatively low thermal budget. Tantalum tends to dewet from oxide at higher thermal budgets. IMP has many of the same coverage advantages for deep hole filling, but IMP tends to operate at a much higher temperature because it produces a high flux of energetic argon ions which dissipate their energy in the layer being deposited. Further, high pressure IMP usually implants some argon into the deposited film. On the contrary, the relatively thin SIP layer is deposited at a relatively high rate and the SIP process is not inherently hot because of the absence of argon. Also, the SIP deposition rates are much faster than with IMP so that any hot deposition is that much shorter, by up to a factor of a half.

The thermal budget is also reduced by a cool ignition of the SIP plasma. A cool plasma ignition and processing sequence is illustrated in the flow diagram of FIG. 14. After the wafer has been inserted through the load lock valve into the sputter reactor, the load lock valve is closed, and in step 410 gas pressures are equilibrated. The argon chamber pressure is raised to that used for ignition, typically between 2 and about 5 to 10 milliTorr, and the argon backside cooling gas is supplied to the back of the wafer at a backside pressure of about 5 to 10 Torr. In step 412, the argon is ignited with a low level of target power, typically in the range of 1 to 5 kW. After the plasma has been detected to ignite, in step 414, the chamber pressure is quickly ramped down, for example over 3 s, with the target power held at the low level. If sustained self-sputtering is planned, the chamber argon supply is turned off, but the plasma continues in the SSS mode. For self-ionized plasma sputtering, the argon supply is reduced. The backside cooling gas continues to be supplied. Once the argon pressure has been reduced, in step 416, the target power is quickly ramped up to the intended sputtering level, for example, 10 to 24 kW or greater for a 200 mm wafer, chosen for the SIP or SSS sputtering. It is possible to combine the steps 414, 416 by concurrently reducing pressure and ramping up the power. In step 418, the target continues to be powered at the chosen level for a length of time necessary to sputter deposit the chosen thickness of material. The target may be sputtered, ionizing the sputtered deposition material in a combined SIP-ICP ionization process or in multistep SIP and ICP processes as described above. In either case, the ignition sequence of FIG. 14 is believed to be cooler than using the intended sputtering power level for ignition. The higher argon pressure facilitates ignition but would deleteriously affect the sputtered neutrals if continued at the higher power levels desired for sputter deposition unless a high pressure ICP ionization is desired for a portion of the film. At the lower ignition power, very little copper is deposited due to the low deposition rate at the reduced power. Also, the pedestal can cooling keep the wafer chilled through the ignition process.

As previously mentioned in the coils 151 and 386 may be operated independently or together. In one embodiment, the coils may be operated together in which the RF signal applied to one coil is phase shifted with respect to the other RF signal applied to the other coil so as to generate a helicon wave. For example, the RF signals may be phase shifted by a fraction of a wavelength as described in U.S. Pat. No. 6,264,812.

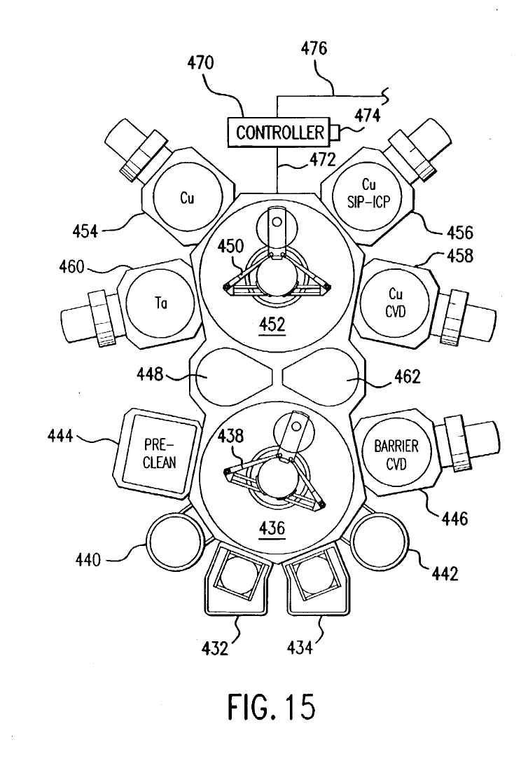

One embodiment of present inventions includes an integrated process preferably practiced on an integrated multi-chamber tool, such as the Endura 5500 platform schematically illustrated in plan view in FIG. 15. The platform is functionally described by Tepman et al. in U.S. Pat. No. 5,186,718.

Wafers which have been already etched with via holes or other structure in a dielectric layer are loaded into and out of the system through two independently operated load lock chambers 432, 434 configured to transfer wafers into and out of the system from wafer cassettes loaded into the respective load lock chambers. After a wafer cassette has been loaded into a load lock chamber 432, 434, the chamber is pump to a moderately low pressure, for example, in the range of 10⁻³ to 10⁻⁴ Torr, and a slit valve between that load lock chamber and a first wafer transfer chamber 436 is opened. The pressure of the first wafer transfer chamber 436 is thereafter maintained at that low pressure.

A first robot 438 located in the first transfer chamber 436 transfer the wafer from the cassette to one of two degassing/orienting chambers 440, 442, and then to a first plasma pre-clean chamber 444, in which a hydrogen or argon plasma cleans the surface of the wafer. If a CVD barrier layer is being deposited, the first robot 438 then passes the wafer to a CVD barrier chamber 446. After the CVD barrier layer is deposited, the robot 438 passes the wafer into a pass through chamber 448, from whence a second robot 450 transfers it to a second transfer chamber 452. Slit valves separate the chambers 444, 446, 448 from the first transfer chamber 436 so as to isolate processing and pressure levels.

The second robot 450 selectively transfers wafers to and from reaction chambers arranged around the periphery. A first IMP sputter chamber 454 may be dedicated to the deposition of copper. An SIP-ICP sputter chamber 456 similar to the chamber 150 described above is dedicated to the deposition of the SIP-ICP copper nucleation layer. This chamber combines ICP deposition for bottom coverage and SIP deposition for sidewall coverage and reduced over hangs in either a one step or a multi-step process as discussed above. Also, at least part of the barrier layer, of, for example, Ta/TaN is being deposited by SIP sputtering and coil sputtering and ICP resputtering, and therefore a second SIP-ICP sputter chamber 460 is dedicated to a sputtering a refractory metal, possibly in a reactive nitrogen plasma. The same SIP-ICP chamber 460 may be used for depositing the refractory metal and its nitride. A CVD chamber 458 is dedicated to the deposition of the copper seed layer and possibly used to complete the filling of the hole. Each of the chambers 454, 456, 458, 460 is selectively opened to the second transfer chambers 452 by slit valves. It is possible to use a different configuration. For example, an IMP chamber 454 may be replaced by a second CVD copper chamber, particularly if CVD is used to complete the hole filling.

After the low-pressure processing, the second robot 450 transfers the wafer to an intermediately placed thermal chamber 462, which may be a cool down chamber if the preceding processing was hot or may be a rapid thermal processing (RTP) chamber is annealing of the metallization is required. After thermal treatment, the first robot 438 withdraws the wafer and transfers it back to a cassette in one of the load lock chambers 432, 434. Of course, other configurations are possible with which the invention can be practiced depending on the steps of the integrated process.

The entire system is controlled by a computer-based controller 470 operating over a control bus 472 to be in communication with sub-controllers associated with each of the chambers. Process recipes are read into the controller 470 by recordable media 474, such as magnetic floppy disks or CD-ROMs, insertable into the controller 470, or over a communication link 476.

Many of the features of the apparatus and process of the inventions can be applied to sputtering not involving long throw. Although the inventions are particularly useful at the present time for tantalum and tantalum nitride liner layer deposition and copper inter-level metallization, the different aspects of the invention may be applied to sputtering other materials and for other purposes. Provisional application No. 60/316,137 filed Aug. 30, 2001 is directed to sputtering and resputtering techniques and is incorporated herein by reference.

The invention thus provides an improved sputtering chamber utilizing a combination of simple elements which nonetheless is effective at sputtering into some difficult geometries. The invention also provides a straightforward process for filling copper into high aspect-ratio holes. All these advantages advance the technology of metal hole filling, particularly with copper, with only simple changes over the prior art.

It will, of course, be understood that modifications of the present invention, in its various aspects, will be apparent to those skilled in the art, some being apparent only after study, others being matters of routine mechanical and process design. Other embodiments are also possible, their specific designs depending upon the particular application. As such, the scope of the invention should not be limited by the particular embodiments herein described but should be defined only by the appended claims and equivalents thereof.

What is claimed is:

1. A method of sputter depositing deposition material onto a substrate in a chamber having a target, comprising:
rotating a magnetron about the back of the target, said magnetron having an area of no more than ¼ of the area of the target and including an inner magnetic pole of one magnetic polarity surrounded by an outer magnetic pole of an opposite magnetic polarity, a magnetic flux of said outer pole being at least 50% larger than the magnetic flux of said inner pole to generate a self-ionized plasma adjacent said target;
applying power to said target to thereby sputter material from said target onto said substrate wherein at least a portion of the sputtered material is ionized in said self-ionized plasma; and
applying RF power to a coil to inductively couple RF energy to generate an inductively coupled plasma adjacent said substrate.

2. The method of claim 1 further comprising biasing said substrate sufficiently to attract ionized deposition material into holes in said substrate having a height to width aspect ratio of at least 4:1.

3. The method of claim 1 further comprising biasing said substrate sufficiently to resputter deposition material from said substrate using ions generated in said inductively coupled plasma.

4. The method of claim 3 further comprising supplying a precursor gas into said chamber wherein said precursor gas is ionized in said inductively coupled plasma to generate said ions used to resputter deposition material from said substrate.

5. The method of claim 1 further comprising ionizing additional sputtered deposition material using said inductively coupled plasma.

6. The method of claim 1 further comprising sputtering material from said coil onto said substrate using said inductively coupled plasma.

7. The method of claim 1 further comprising controlling the DC bias on said coil using a DC source coupled to said coil to control the rate at which coil material is sputtered from said coil.

8. The method of claim 7 wherein said controlling includes using a blocking capacitor coupled to said coil to support a DC bias on said coil.

9. The method of claim 1 further comprising in a first step, biasing said substrate sufficiently to attract ionized deposition material into holes in said substrate having a height to width aspect ratio of at least 3:1 to form a layer of deposition material in said hole wherein said layer has a bottom portion and a sidewall portion, and, in a second step, biasing said substrate sufficiently to resputter deposition material from the bottom portion of said hole using ions generated in said inductively coupled plasma to at least thin said bottom portion while at least reducing the power applied to said target to reduce the amount of material sputtered from said target during said second step.

10. The method of claim 9 wherein said power applied to said target is reduced to less than 1 kW during at least a portion of said second step.

11. The method of claim 9 wherein said power applied to said target is reduced to less than 200 watts during at least a portion of said second step.

12. The method of claim 9 wherein said RF power applied to said coil is less than 500 watts during at least a portion of said first step and is greater than 500 watts during at least a portion of said second step.

13. The method of claim 12 wherein said RF power applied to said coil is 0 watts during at least a portion of said first step and is at least 1 kW during at least a portion of said second step.

14. The method of claim 9 further comprising sputtering coil material from said coil onto said sidewall portion of said layer while resputtering deposition material from said layer bottom portion using said inductively coupled plasma during said second step.

15. The method of claim 14 wherein said coil sputtering includes applying DC power to said coil during at least a portion of said second step.

16. The method of claim 14 wherein said layer is a barrier layer.

17. The method of claim 16 wherein said barrier layer comprises tantalum nitride.

18. The method of claim 14 wherein said layer is a liner layer.

19. The method of claim 18 wherein said liner layer comprises tantalum.

20. The method of claim 1 wherein the pressure within said chamber is less than 5 mTorr when applying RF power to said coil.

21. The method of claim 1 wherein said target is spaced from a pedestal for holding said substrate by a throw distance that is greater than 50% of a diameter of the substrate.

22. The method of claim 21 wherein said throw distance is greater than 80% of said diameter of the substrate.

23. The method of claim 22, wherein said throw distance is greater than 140% of said diameter of the substrate.

24. The method of claim 1, wherein said material is copper which is deposited into a hole formed in a dielectric layer of said substrate and having a height to width aspect ratio of at least 4:1.

25. A method of depositing material into holes each having an aspect ratio of at least 4:1 and formed in a dielectric layer of a substrate, comprising:
sputtering a target of a chamber using a magnetron which generates a self-ionized plasma which ionizes the material sputtered from the target;
depositing sputtered material ionized in the self-ionized plasma into said holes of a substrate in said chamber; and
generating an inductively coupled plasma in said chamber using an RF coil to further process said substrate.

26. The method of claim 25 wherein said depositing includes biasing said substrate sufficiently to attract ionized deposition material into said holes in said substrate.

27. The method of claim 25 further comprising biasing said substrate sufficiently to resputter deposition material from said holes in said substrate using ions generated in said inductively coupled plasma.

28. The method of claim 27 further comprising supplying a precursor gas into said chamber wherein said precursor gas is ionized in said inductively coupled plasma to generate said ions used to resputter deposition material from said substrate.

29. The method of claim 25 further comprising ionizing additional sputtered deposition material using said inductively coupled plasma.

30. The method of claim 25 further comprising sputtering material from said coil onto said substrate using said inductively coupled plasma.

31. The method of claim 30 further comprising controlling the DC bias on said coil using a DC source coupled to said coil to control the rate at which coil material is sputtered from said coil.

32. The method of claim 31 wherein said controlling includes using a blocking capacitor coupled to said coil to support a DC bias on said coil.

33. The method of claim 25 wherein said depositing includes biasing said substrate sufficiently to attract ionized deposition material into said holes in said substrate to form a layer of deposition material in said hole wherein said layer has a bottom portion and a sidewall portion, and, in a second step, biasing said substrate sufficiently to resputter deposition material from the bottom portion of said hole using ions generated in said inductively coupled plasma, to at least thin said bottom portion while at least reducing the power applied to said target to reduce the amount of material sputtered from said target during said second step.

34. A method of sputter depositing deposition material onto a substrate, comprising:
providing a chamber having a target;
rotating a magnetron about the back of the target, said magnetron having an area of no more than about ¼ of the area of the target and including an inner magnetic pole of one magnetic polarity surrounded by an outer magnetic pole of an opposite magnetic polarity, a magnetic flux of said outer pole being at least 50% larger than the magnetic flux of said inner pole;
applying power to said target to thereby sputter material from said target onto said substrate at a first rate; and
applying RF power to a first coil to provide a plasma to resputter deposition material on said substrate in said chamber.

35. The method of claim 34 wherein said target is spaced from a pedestal for holding said substrate by a throw distance that is greater than 50% of a diameter of the substrate.

36. The method of claim 34 further comprising sputtering said coil to deposit coil material onto said substrate while resputtering target material on said substrate.

37. The method of claim 36 further comprising inhibiting sputtering said target while resputtering target material on said substrate.

38. A method of depositing material into holes each having an aspect ratio of at least 4:1 and formed in a dielectric layer of a substrate, comprising:
ionizing sputtered target material in a magnetron generated self-ionized plasma in a chamber;
depositing sputtered material ionized in the self-ionized plasma into said holes of a substrate in said chamber; and
resputtering material from a portion a bottom of each of said holes in an inductively coupled plasma in said chamber.

39. The method of claim 38 further comprising sputter depositing RF coil material around said holes in said inductively coupled plasma in said chamber.

40. A method of forming a barrier layer and a liner layer into holes formed in a dielectric layer of a substrate, comprising:
operating a magnetron to generate a self-ionized plasma adjacent a target in a chamber;
sputtering said target to provide sputtered target material wherein at least a portion of said sputtered target material is ionized in said self-ionized plasma;
biasing said substrate in said chamber to deposit into each of said holes a barrier layer comprising sputtered target material ionized in said magnetron generated self-ionized plasma in said chamber;
operating an RF coil to generate an inductively coupled plasma in said chamber;
sputtering coil material from said RF coil onto said substrate in said chamber;
resputtering bottom portions of said barrier layers using said inductively coupled plasma in said chamber to thin said bottom portions of said barrier layers;
operating said magnetron to generate additional self-ionized plasma adjacent said target in said chamber;
sputtering said target to provide additional sputtered target material wherein at least a portion of said additional sputtered target material is ionized in said additional self-ionized plasma;
biasing said substrate in said chamber to deposit into each of said holes a liner layer comprising said additional sputtered target material ionized in said additional magnetron generated self-ionized plasma in said chamber;
operating said RF coil to generate additional inductively coupled plasma in said chamber;
sputtering additional coil material from said RF coil onto said substrate in said chamber; and
resputtering bottom portions of said liner layers using said additional inductively coupled plasma in said chamber to thin said bottom portions of said liner layers.

41. A plasma sputter reactor for sputter depositing a film on a substrate, comprising:
a vacuum chamber containing a pedestal aligned to a chamber axis and having a support surface for supporting a substrate to be sputter deposited;
a target comprising a material to be sputter deposited on said substrate and electrically isolated from said vacuum chamber;
a magnetron disposed adjacent said target and having an area of no more than about ¼ of the area of the target and including an inner magnetic pole of one magnetic polarity surrounded by an outer magnetic pole of an opposite magnetic polarity, a magnetic flux of said outer pole being at least 50% larger than the magnetic flux of said inner pole, and adapted to generate a self-ionized plasma in said chamber adjacent said target to ionize deposition material sputtered from said target; and
a first RF coil disposed between said target and said pedestal and adapted to inductively couple RF energy to generate an inductively coupled plasma in a plasma generation area between said target and pedestal.

42. The reactor of claim 41 further comprising a first electrically conductive shield generally symmetric about said axis, and disposed within said chamber wherein said coil is generally symmetric about said axis and is insulatively supported by said shield.

43. The reactor of claim 41 further comprising a pressure pump coupled to said chamber and a controller adapted to control the pressure pump and the pressure in said chamber to a pressure of no more than 5 millitorr during at least a first portion of said sputter depositing.

44. The reactor of claim 41 further comprising a source coupled to said coil and a controller adapted to control said source to bias said substrate sufficiently to attract ionized deposition material into holes in said substrate having a height to width aspect ratio of at least 4:1.

45. The reactor of claim 44 wherein said controller is adapted to control said source to bias said substrate sufficiently to resputter deposition material from said substrate using ions generated in said inductively coupled plasma.

46. The reactor of claim 45 further comprising a precursor gas supply wherein said controller is adapted to control said supply to supply a precursor gas into said chamber wherein said precursor gas is ionized in said inductively coupled plasma to generate said ions used to resputter deposition material from said substrate.

47. The reactor of claim 41 wherein said coil is adapted to be sputtered, said reactor further comprising a DC source coupled to said coil and a controller adapted to control said DC source to control the DC bias on said coil to control the rate at which coil material is sputtered from said coil.

48. The reactor of claim 47 further comprising a blocking capacitor coupled to said coil to support a DC bias on said coil.

49. The reactor of claim 41 further comprising a biasing source coupled to said pedestal and a controller adapted to control said biasing source, in a first step, to bias said substrate sufficiently to attract ionized deposition material into holes in said substrate having a height to width aspect ratio of at least 3:1 to form a layer of deposition material in each of said holes wherein said layer has a bottom portion and a sidewall portion, and, in a second step, to bias said substrate sufficiently to resputter deposition material from the bottom portion of said layers using ions generated in said inductively coupled plasma to at least thin said bottom portions while at least reducing the power applied to said target to reduce the amount of material sputtered from said target during said second step.

50. The reactor of claim 49 further comprising a power source adapted to apply power to said target wherein said controller is adapted to control the target power source to reduce the power applied to said target to less than 1 kW during at least a portion of said second step.

51. The reactor of claim 49 wherein said power applied to said target is reduced to less than 200 watts during at least a portion of said second step.

52. The reactor of claim 51 wherein said no material is sputtered from said target during at least a portion of said second step.

53. The reactor of claim 49 further comprising an RF power source adapted to apply RF power said coil wherein said controller is adapted to control the coil RF power source to apply RF power to said coil at less than 500 watts during at least a portion of said first step and at greater than 500 watts during at least a portion of said second step.

54. The reactor of claim 53 wherein said RF power applied to said coil is 0 watts during at least a portion of said first step and is at least 1 kW during at least a portion of said second step.

55. The reactor of claim 49 further comprising a DC power source adapted to apply DC power to said coil wherein said controller is adapted to control the coil DC power source to apply DC power to said coil to control coil sputtering during at least a portion of said second step.

56. The reactor of claim 55 wherein said controller is adapted to control said coil DC power source to sputter coil material from said coil onto said sidewall portion of said layers while resputtering deposition material from said layer bottom portions using said inductively coupled plasma during said second step

57. The reactor of claim 41 wherein said target material comprises tantalum.

58. The reactor of claim 47 wherein said coil material comprises tantalum.

59. The reactor of claim 41 wherein said target is spaced from said pedestal by a throw distance that is greater than 50% of a diameter of the substrate.

60. The reactor of claim 59 wherein said throw distance is greater than 80% of said diameter of the substrate.

61. The reactor of claim 60, wherein said throw distance is greater than 140% of said diameter of the substrate.

62. A plasma sputter reactor for sputter depositing a film on a substrate, comprising:
a vacuum chamber containing a pedestal aligned to a chamber axis and having a support surface for supporting a substrate to be sputter deposited;
a target comprising a material to be sputter deposited on said substrate and electrically isolated from said vacuum chamber;
a magnetron disposed adjacent said target and having an area of no more than about ¼ of the area of the target and including an inner magnetic pole of one magnetic polarity surrounded by an outer magnetic pole of an opposite magnetic polarity, a magnetic flux of said outer pole being at least 50% larger than the magnetic flux of said inner pole, and adapted to generate a self-ionized plasma in said chamber adjacent said target to ionize deposition material sputtered from said target; and
a first RF coil disposed between said target and said pedestal and adapted to inductively couple RF energy to generate an inductively coupled plasma in a plasma generation area between said target and pedestal to resputter target deposition material from said substrate.

63. The reactor of claim 62 wherein said coil is adapted to be sputtered, said reactor further comprising a DC source coupled to said coil and a controller adapted to control said DC source to control the DC bias on said coil to control the rate at which coil material is sputtered from said coil.

64. The reactor of claim 63 further comprising a blocking capacitor coupled to said coil to support a DC bias on said coil.

65. A plasma sputter reactor for sputter depositing a film on a substrate having a plurality of holes, comprising:
a vacuum chamber containing a pedestal aligned to a chamber axis and having a support surface for supporting a substrate to be sputter deposited;
a controller;
a pedestal power source responsive to said controller and coupled to said pedestal and adapted to bias said substrate supported on said pedestal support surface;
a target comprising a material to be sputter deposited on said substrate and electrically isolated from said vacuum chamber wherein said target is spaced from said pedestal by a throw distance that is greater than 50% of a diameter of the substrate;
a magnetron responsive to said controller and disposed adjacent said target and having an area of no more than about ¼ of the area of the target and including an inner magnetic pole of one magnetic polarity surrounded by an outer magnetic pole of an opposite magnetic polarity, a magnetic flux of said outer pole being at least 50% larger than the magnetic flux of said inner pole, and adapted to generate a self-ionized plasma in said chamber adjacent said target to ionize deposition material sputtered from said target;
a target power source coupled to said target and responsive to said controller to bias said target to cause target material to be sputtered from said target;
a first electrically conductive shield generally symmetric about said axis and disposed within said chamber;
an RF coil generally symmetric about said axis and insulatively carried by said shield and disposed between said target and said pedestal;
an RF power source responsive to said controller and coupled to said RF coil to power said RF coil to inductively couple RF energy to generate an inductively coupled plasma in a plasma generation area between said target and pedestal; and
a coil biasing source responsive to said controller and coupled to said RF coil and adapted to bias said RF coil to cause coil material to be sputtered from said RF coil;
wherein said controller is adapted to:
operate said magnetron to generate a self-ionized plasma adjacent said target;
operate said target power source to bias said target to sputter said target to provide sputtered target material wherein at least a portion of said sputtered target material is ionized in said self-ionized plasma;
operate said pedestal power source to bias said substrate in said chamber to deposit into each of said holes a barrier layer comprising sputtered target material ionized in said magnetron generated self-ionized plasma in said chamber;
operate said RF source to operate said RF coil to generate an inductively coupled plasma in said chamber;
operate said coil biasing source to bias said RF coil to sputter coil material from said RF coil onto said substrate in said chamber;
operate said pedestal power source to bias said substrate to resputter bottom portions of said barrier layers using said inductively coupled plasma in said chamber to thin said bottom portions of said barrier layers;
operate said magnetron to generate additional self-ionized plasma adjacent said target in said chamber;
operate said target power source to bias said target to sputter said target to provide additional sputtered target material wherein at least a portion of said additional sputtered target material is ionized in said additional self-ionized plasma;
operate said pedestal power source to bias said substrate in said chamber to deposit into each of said holes a liner layer comprising said additional sputtered target material ionized in said additional magnetron generated self-ionized plasma in said chamber;
operate said RF power source to operate said RF coil to generate additional inductively coupled plasma in said chamber;
operate said coil biasing source to bias said RF coil to sputter additional coil material from said RF coil onto said substrate in said chamber; and
operate said pedestal power source to bias said substrate to resputter bottom portions of said liner layers using said additional inductively coupled plasma in said chamber to thin said bottom portions of said liner layers.

66. The reactor of claim 65 wherein said target material and said coil material comprises tantalum and said barrier layer comprises tantalum nitride and said liner layer comprises tantalum.

67. A reactor for depositing conductive material onto a substrate, comprising:
target means for sputter depositing a layer of conductive material onto said substrate, and for generating a self ionized plasma to ionize a portion of said conductive material sputtered from said target means prior to being deposited onto said substrate; and
inductively coupled plasma means for generating an inductively coupled plasma adjacent said substrate.

68. A reactor for depositing conductive material onto a substrate, comprising:
pedestal means for supporting a substrate;
target means for sputter depositing a layer of conductive material onto said substrate, and for generating a self ionized plasma to ionize a portion of said conductive material sputtered from said target means prior to being deposited onto said substrate;
means for biasing said substrate to attract ionized conductive material from said target means to deposit onto said substrate;
inductively coupled plasma means for generating an inductively coupled plasma containing ions within said chamber, said inductively coupled plasma means including an RF coil of conductive material;
said substrate biasing means further for biasing said substrate to attract said ions from said inductively coupled plasma to resputter from said substrate conductive material deposited on said substrate from said target means; and
means for sputtering said coil to deposit coil material onto said substrate while target means conductive material is resputtered from said substrate;
wherein said pedestal means includes a substrate support surface and said target means includes a target which is spaced from said substrate support surface by a throw distance that is greater than 50% of a diameter of the substrate.

69. A method of sputter depositing deposition material onto a substrate, comprising:
providing a chamber having a target;
rotating a magnetron about the back of the target, said magnetron having an area of no more than about ¼ of the area of the target and including an inner magnetic pole of one magnetic polarity surrounded by an outer magnetic pole of an opposite magnetic polarity, a magnetic flux of said outer pole being at least 50% larger than the magnetic flux of said inner pole;
applying power to said target to thereby sputter material from said target onto said substrate; and
applying RF power to a first coil to provide additional plasma density in said chamber.

70. The method of claim 69 wherein said target is spaced from a pedestal for holding said substrate by a throw distance that is greater than 50% of a diameter of the substrate.

71. The method of claim 69 wherein further comprising applying RF power to a second coil to provide additional plasma density.

72. The method of claim 71 wherein said first coil is positioned closer to said target than said substrate pedestal and said second coil is positioned closer to said substrate pedestal than said target.

73. The method of claim 72 wherein said second coil provides more additional plasma density than said first coil during a first interval while target material is sputtered onto said substrate.

74. The method of claim 73 wherein said first coil provides more additional plasma density than said second coil during a second interval while target material is sputtered onto said substrate.

75. The method of claim 69 further comprising, after a plasma has been ignited in the chamber, pumping said chamber to a pressure of no more than 5 milliTorr during at least a first portion of said target power applying.

76. The method of claim 75 further comprising pumping said pressure to a pressure greater than 5 milliTorr during a second portion of target power applying.

77. The method of claim 76 wherein during said second portion, said pressure greater than 5 mTorr is at least 20 mTorr, said RF power is at least 1 kW, and said target power is less than 10 kW.

78. The method of claim 76 wherein during said second portion, said pressure greater than 5 mTorr is at 20-40 mTorr, said RF power is at 1-3 kW, and said target power is at 1-2 kW DC.

79. The method of claim 75 wherein during said first portion, said RF power is at least 1 kW and said target power is at least 10 kW DC.

80. The method of claim 79 wherein during said first portion, said RF power is at least 1 kW and said target power is at least 18 kW DC.

81. The method of claim 75 wherein no RF power is applied to said coil during said first portion of said target power applying.

82. The method of claim 75, wherein said target is spaced from a pedestal for holding said substrate by a throw distance that is greater than 50% of a diameter of the substrate and wherein said pressure is less than 2 milliTorr.

83. The method of claim 82, wherein said throw distance is greater than 80% of said diameter of the substrate.

84. The method of claim 83, wherein said throw distance is greater than 140% of said diameter of the substrate.

85. The method of claim 75, wherein said pressure is less than 2 milliTorr.

86. The method of claim 85, wherein said pressure is less than 1 milliTorr.

87. The method of claim 86, wherein said target is spaced from a pedestal for holding said substrate by a throw distance that is greater than 80% of said diameter of the substrate.

88. The method of claim 75, wherein said substrate is a 200 mm wafer and said target power applying step applies at least 18 kW of DC power to said target normalized to said 200 mm wafer.

89. The method of claim 76 further comprising applying power to a support supporting said substrate to bias said substrate.

90. The method of claim 89 wherein during said applying power to said support is applied at a higher level during said first portion than said second portion.

91. The method of claim 90 wherein during said applying power to said support is applied at approximately 500 watts during said first portion and at approximately 150 watts during said second portion.

92. The method of claim 88, wherein said target power applying power applies at least 24 kW of DC power to said target normalized to said 200 mm wafer.

93. The method of claim 75, wherein said substrate is a 200 mm wafer, said pressure is less than 1 milliTorr, said target is spaced from a pedestal for holding said substrate by a throw distance that is greater than 140% of said substrate diameter, and said target applying power applies at least 24 kW of Dc power to said target normalized to said 200 mm wafer.

94. The method of claim 69, wherein said material is copper which is deposited into a hole formed in a dielectric layer of said substrate and having an aspect ratio of at least 4:1.

95. The method of claim 94, wherein said copper is deposited to a thickness of between 50 to 300 nm on a top planar surface of said substrate and further comprising filling copper into a remainder of said hole.

96. The method of claim 95, wherein said thickness is between 150 to 200 nm.

97. The method of claim 95, wherein said filling comprises electroplating.

98. The method of claim 95, wherein said filling comprises chemical vapor deposition.

99. The method of claim 76, wherein said material is copper which is deposited into a hole formed in a dielectric layer of said substrate and having an aspect ratio of at least 4:1, and wherein said copper is deposited to a thickness of between 100 to 200 nm on a top planar surface of said substrate during said first portion and deposited to a thickness of between 50 to 100 nm on a top planar surface of said substrate during said second portion.

100. A method of depositing copper into a hole having an aspect ratio of at least 4:1 and formed in a dielectric layer of a substrate, comprising:
sputter depositing a first copper layer in a self-ionized plasma in a chamber to form a copper layer on at least a first portion of the walls of said hole but not filling said hole;
sputter depositing a second copper layer in an inductively coupled plasma in said chamber to form another copper layer on at least a second portion of the walls of said hole but not filling said hole; and
depositing a third copper layer onto said first and second layers.

101. The method of claim 100, wherein said sputter depositing a second copper layer is performed after said sputtering depositing a first copper layer.

102. The method of claim 100, wherein said sputter depositing a second copper layer is performed at the same time as said sputter depositing a first copper layer.

103. The method of claim 100, wherein said sputter depositing a second copper at least partially uses RF inductive coupling to form said inductively coupled plasma.

104. The method of claim 100, wherein said first copper layer has a first blanket thickness of copper and said second copper layer has a second blanket thickness of copper, a ratio of said first to said second blanket thicknesses being in a range of 4:1 to 1:1.

105. The method of claim 100, wherein said depositing a third copper layer comprises electroplating.

106. The method of claim 100, wherein said depositing a first copper layer is performed at a chamber pressure of less than 5 milliTorr.

107. The method of claim 100, wherein said first layer has a thickness on a top surface of said dielectric layer of 100 to 200 nm.

108. The method of claim 100, wherein said second layer has a thickness on a top surface of said dielectric layer of 50 to 100 nm.

109. The method of claim 100, wherein said depositing a third copper layer fills said hole with copper.

110. The method of claim 100, wherein said depositing a third copper layer comprises chemical vapor deposition.

111. The method of claim 110, further comprising depositing a fourth copper layer which includes electroplating said fourth layer comprising copper onto said third layer to thereby fill said hole with copper.

112. The method of claim 110, wherein depositing a third copper layer fills said hole with copper.

113. A method of sputter depositing copper onto a substrate, comprising:
providing a chamber having target principally comprising copper spaced from a pedestal for holding a substrate to be sputter coated by a throw distance that is greater than 50% of a diameter of the substrate;
rotating a magnetron about the back of the target, said magnetron having an area of no more than about ¼ of the area of the target and including an inner magnetic pole of one magnetic polarity surrounded by an outer magnetic pole of an opposite magnetic polarity, a magnetic flux of said outer pole being at least 50% larger than the magnetic flux of said inner pole;
after a plasma has been ignited in the chamber, pumping said chamber to a pressure of no more than 5 milliTorr;
applying at least 10 kW of DC power to said target normalized to a 200 mm wafer while said chamber is pumped to said pressure, to thereby sputter copper from said target onto said substrate; and
applying RF power to a coil to provide additional plasma density.

114. A plasma sputter reactor for sputter depositing a film on a substrate, comprising:
a metallic vacuum chamber containing a pedestal aligned to a chamber axis and having a support surface for supporting a substrate to be sputter deposited;
a target comprising a material to be sputter deposited on said substrate and electrically isolated from said vacuum chamber;
a magnetron disposed adjacent said target and having an area of no more than about ¼ of the area of the target and including an inner magnetic pole of one magnetic polarity surrounded by an outer magnetic pole of an opposite magnetic polarity, a magnetic flux of said outer pole being at least 50% larger than the magnetic flux of said inner pole;
a first electrically conductive shield generally symmetric about said axis, supported on and electrically connected to said chamber, and extending away from said target along a wall of said chamber to an elevation behind said support surface;
a first RF coil insulatively carried by said first shield; and
a controller adapted to control the pressure in said chamber to a pressure of no more than 5 milliTorr during at least a first portion of said sputter depositing.

115. The reactor of claim 113 further comprising:
a second RF coil insulatively carried within said chamber.

116. The reactor of claim 113 further comprising:
an electrical isolator supported by said chamber;
a second electrically conductive shield generally symmetric about said axis, supported on said isolator, electrically isolated from said chamber and from said target; and
a second RF coil insulatively carried by said second shield.

117. The reactor of claim 114 wherein said target is spaced from a pedestal for holding said substrate by a throw distance that is greater than 50% of a diameter of the substrate.

118. The reactor of claim 114 further comprising a first RF generator adapted to apply RF power to said first coil.

119. The reactor of claim 115 wherein said first coil is positioned closer to said target than said substrate support and said second coil is positioned closer to said substrate support than said target.

120. The reactor of claim 119 further comprising a first RF generator adapted to apply RF power to said first coil and a second RF generator adapted to apply RF power to said second coil and wherein said controller is adapted to provide greater RF power to said second coil than said first coil during a first interval while target material is sputtered onto said substrate.

121. The reactor of claim 120 wherein said controller is adapted to provide greater RF power to said first coil than said second coil during a second interval while target material is sputtered onto said substrate.

122. The reactor of claim 118 wherein said controller is adapted to control said pressure to a pressure greater than 5 milliTorr during a second portion of said sputter depositing while RF power is applied to said coil.

123. The reactor of claim 122 further comprising a DC power supply responsive to said controller and adapted to provide target power to said target.

124. The reactor of claim 123 wherein during said second portion, said pressure greater than 5 mTorr is at least 20 mTorr, said RF power is at least 1 kW, and said target power is less than 10 kW.

125. The reactor of claim 123 wherein during said second portion, said pressure greater than 5 mTorr is at 20-40 mTorr, said RF power is at 1-3 kW, and said target power is at 1-2 kW DC.

126. The reactor of claim 114 further comprising a first RF generator responsive to said controller and adapted to apply RF power to said first coil wherein during said first portion, said RF power is at least 1 kW.

127. The reactor of claim 126 further comprising a DC power supply responsive to said controller and adapted to provide target power to said target wherein during said first portion, said target power is at least 10 kW DC.

128. The reactor of claim 127 wherein during said first portion, said target power is at least 18 kW DC.

129. The reactor of claim 118 wherein said controller is adapted to control said RF generator to provide no RF power during said first portion of said sputter depositing.

130. The reactor of claim 118, wherein said target is spaced from a pedestal for holding said substrate by a throw distance that is greater than 50% of a diameter of the substrate and wherein said pressure is less than 2 milliTorr.

131. The reactor of claim 130, wherein said throw distance is greater than 80% of said diameter of the substrate.

132. The reactor of claim 131, wherein said throw distance is greater than 140% of said diameter of the substrate.

133. The reactor of claim 114, wherein said pressure is less than 2 milliTorr.

134. The reactor of claim 133, wherein said pressure is less than 1 milliTorr.

135. The reactor of claim 134, wherein said target is spaced from a pedestal for holding said substrate by a throw distance that is greater than 80% of said diameter of the substrate.

136. The reactor of claim 114 further comprising a DC power supply, wherein said substrate is a 200 mm wafer and said controller is adapted to apply at least 18 kW of DC power to said target normalized to said 200 mm wafer.

137. The reactor of claim 136, wherein said controller applies at least 24 kW of DC power to said target normalized to said 200 mm wafer.

138. The reactor of claim 46, wherein said substrate is a 200 mm wafer, said pressure is less than 1 milliTorr, said target is spaced from a pedestal for holding said substrate by a throw distance that is greater than 140% of said substrate diameter.

139. The reactor of claim 122 further comprising a source responsive to said controller and adapted to apply power to said support surface supporting said substrate to bias said substrate.

140. The reactor of claim 139 wherein said support power applied to said support is applied at a higher level during said first portion than said second portion.

141. The reactor of claim 140 wherein said support power applied to said support is applied at approximately 500 watts during said first portion and at approximately 150 watts during said second portion.

142. A reactor for depositing conductive material onto a substrate, comprising:
target means for sputter depositing a layer of conductive material onto said substrate, and for generating a self ionized plasma to ionize a portion of said conductive material sputtered from said target means prior to being deposited onto said substrate; and
inductively coupled plasma means for generating an inductively coupled plasma to ionize a portion of said conductive material sputtered from said target means prior to being deposited onto said substrate.

143. The reactor of claim 142 wherein said target means includes a target comprising a conductive material to be sputter deposited on said substrate and a magnetron disposed adjacent said target and having an area of no more than about ¼ of the area of the target and including an inner magnetic pole of one magnetic polarity surrounded by an outer magnetic pole of an opposite magnetic polarity, a magnetic flux of said outer pole being at least 50% larger than the magnetic flux of said inner pole.

144. The reactor of claim 142 wherein said inductively coupled plasma means includes an RF coil disposed between said target means and said substrate, and RF generator means for applying RF energy to said RF coil.
